(19) United States
(12) Patent Application Publication
(10) Pub. No.: US 2024/0012473 A1
(43) Pub. Date: Jan. 11, 2024

(54) Methods, Apparatuses And Computer Program Products For Providing Multi-Functional Optical Modules With Micro-Light Emitting Diodes As Eye Tracking Illumination Sources

(71) Applicant: META PLATFORMS TECHNOLOGIES, LLC, Menlo Park, CA (US)

(72) Inventors: Wei Wu, Bellevue, WA (US); Mehmet Mutlu, Redmond, WA (US); Alfredo Bismuto, Redmond, WA (US); Qi Zhang, Kirkland, WA (US); Kuan Pei Yap, San Jose, CA (US)

(21) Appl. No.: 18/306,955

(22) Filed: Apr. 25, 2023

Related U.S. Application Data
(63) Continuation-in-part of application No. 17/862,231, filed on Jul. 11, 2022.

(51) Int. Cl. G06F 3/01; G06T 19/00

(52) U.S. Cl. CPC G06F 3/013; G06T 19/006

(57) ABSTRACT

Systems, methods, and devices for eye tracking are provided. A device may include a multi-functional optical module including a plurality of optical lens layers. The device may include a layer, among the plurality of optical lens layers, including a patterned substrate including a plurality of light emitting diodes in a field of view of the layer and a plurality of wires configured to connect to a printed circuit board assembly. The light emitting diodes in the field of view may be configured to illuminate light directed to at least one eye of a user to cause at least one reflection of the at least one eye.

### CROSS-REFERENCE TO RELATED APPLICATIONS

This application is a continuation in part of U.S. application Ser. No. 17/862,231 filed Jul. 11, 2022, entitled “Optical Assembly With Micro Light Emitting Diode (LED) As Eye-Tracking Near Infrared (nIR) Illumination Source,” the entire contents of which are incorporated in its entirety herein by reference.

### TECHNICAL FIELD

This patent application relates generally to optical assemblies using eye-tracking techniques, and more specifically, to systems and methods using a micro light emitting diode as an eye-tracking near infrared (nIR) illumination source. This patent application also relates generally to methods, apparatuses and computer program products for providing a multi-functional optical module having integrated illumination sources to facilitate eye tracking for artificial reality systems.

### BACKGROUND

With recent advances in technology, prevalence and proliferation of content creation and delivery has increased greatly in recent years. In particular, interactive content such as virtual reality (VR) content, augmented reality (AR) content, mixed reality (MR) content, and content within and associated with a real and/or virtual environment (e.g., a “Metaverse”) has become appealing to consumers.

To facilitate delivery of this and other related content, service providers have endeavored to provide various forms of wearable display systems. One such example may be a head-mounted display (HMD) device, such as a wearable eyewear, a wearable headset, or eyeglasses. In some examples, the head-mounted display (HMD) device may project or direct light to form a first image and a second image, and with these images, to generate “binocular” vision for viewing by a user.

Eye-tracking may be used in some head-mounted display (HMD) devices. It may be important for components of an eye-tracking system to balance any number of system criteria, such as power consumption, size, weight, reliability, ease of manufacture, and cost.

### BRIEF SUMMARY

Exemplary embodiments are described for developing a new multi-functional optical module (MFOM) having integrated near-infrared micro-scale light emitting diodes (LEDs), as illumination sources, for an eye tracking system(s). The eye tracking system(s) may be utilized in virtual reality (VR), augmented reality (AR), mixed reality (MR), hybrid reality, or the like, applications. In this regard, the eye tracking system(s) may be utilized with smart glasses (e.g., artificial reality glasses).

The eye tracking system(s) of the exemplary embodiments may include the multi-functional optical module which may include a plurality of components and multiple optical layers, as described more fully below. For example, the multi-functional optical module may include a plurality of micro-LEDs (e.g., 6 or more, 7 or more, etc.) bonded on a patterned substrate layer of the multi-functional optical module. The micro-LEDs may have a length and width less than 250 micrometers (μm) or up to 250 μm (e.g., 100 μm to 250 μm, etc.). The micro-LEDs may also be referred to herein as in-field LEDs since the micro-LEDs of the exemplary embodiments may be directly in the field of view of lenses of smart glasses from which a user may view an environment (e.g., a real world environment, a virtual/augmented/mixed reality environment).

The micro-LEDs may be illumination sources to illuminate light onto an eye(s) of a user to cause a reflection. The light illuminated by the micro LEDs may be light having a near-infrared wavelength. For purposes of illustration and not of limitation, in some exemplary embodiments, the micro-LEDs may operate with a peak wavelength in a range of 800 nanometers (nm) to 1,000 nm. The reflection may be captured as an image(s) (e.g., glint image(s)) by one or more cameras. For instance, the eye tracking system may include one or more cameras to capture the images (e.g., glint images) of an eye(s). In some exemplary embodiments, the eye tracking system may include at least two (e.g., 2 or more) cameras on a frame associated with smart glasses of the eye tracking system(s). For purposes of illustration, and not of limitation, a first camera may be arranged on a frame (e.g., temporal side of a frame) of the smart glasses and a second camera may be arranged on a nasal component of the frame of the smart glasses. In this manner, the first camera and the second camera may capture a full view in an image(s) of both sides of an eye(s) of a user looking at different gaze angles. In other exemplary embodiments, the cameras of the eye tracking system(s) may be arranged in other areas of the frame of the smart glasses. The eye tracking system(s) and the multi-functional optical module of the exemplary embodiments may include additional components and/or optical layers, as described more fully below.

In some aspects of the present disclosure, a device for eye tracking is provided. The device may include one or more processors and at least one memory storing instructions. The device may include a multi-functional optical module including a plurality of optical lens layers. The device may also include a layer, among the plurality of optical lens layers, including a patterned substrate including a plurality of light emitting diodes in a field of view of the layer and a plurality of wires configured to connect to a printed circuit board assembly. The memory and computer program code are configured to, with the one or more processors, cause the device to enable the light emitting diodes in the field of view to illuminate light directed to at least one eye of a user to cause at least one reflection of the at least one eye.

In some other aspects of the present disclosure, a method for eye tracking is provided. The method may include providing a multi-functional optical module including a plurality of optical lens layers in at least one device. The method may further include enabling a layer, among the plurality of optical lens layers in the at least one device, including a patterned substrate including a plurality of light emitting diodes in a field of view of the layer and a plurality of wires to connect to a printed circuit board assembly. The method may further include causing, by the light emitting diodes in the field of view, illumination of light directed to at least one eye of a user to cause at least one reflection of the at least one eye.

In yet some other aspects of the present disclosure, a computer program product for eye tracking is provided. The computer program product may include at least one computer-readable storage medium having computer-executable program code instructions stored therein. The computer-executable program code instructions may include program code instructions configured to facilitate illumination, by a plurality of light emitting diodes in a field of view of a layer among a plurality of optical lens layers in at least one device, of light directed to at least one eye of a user to cause at least one reflection of the at least one eye. The multi-functional optical module includes the plurality of optical lens layers in the at least one device. The layer may include a patterned substrate including the plurality of light emitting diodes in the field of view of the layer and a plurality of wires to connect to a printed circuit board assembly. The computer program product may further include program code instructions configured to capture, based on the at least one reflection, at least one image of the at least one eye.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1 illustrates a block diagram of an artificial reality system environment including a near-eye display, according to an example.

FIG. 2 illustrates a perspective view of a near-eye display in the form of a head-mounted display (HMD) device, according to an example.

FIG. 3 illustrates a perspective view of a near-eye display in the form of a pair of glasses, according to an example.

FIG. 4 illustrates a perspective view of an optical assembly with bonded micro light emitting diodes (LEDs), in accordance with various examples.

FIG. 5 illustrates a plan view of an optical assembly with bonded micro light emitting diodes, in accordance with various examples.

FIG. 6 illustrates an expanded view of an optical assembly with bonded micro light emitting diodes, in accordance with various examples.

FIG. 7 illustrates a cross-sectional view of a patterned substrate, an encapsulating material, a thermal debonding film, a protective film, and a glass carrier, according to an example.

FIG. 8 illustrates a diagram of an example head-mounted display (HMD) device according to various examples.

FIG. 9 is a diagram of an exemplary network environment in accordance with an example of the present disclosure.

FIG. 10 illustrates an artificial reality system comprising a headset, in accordance with examples of the present disclosure.

FIG. 11 is a diagram of an exemplary communication device in accordance with an example of the present disclosure.

FIG. 12A is a diagram illustrating a multi-functional optical module in accordance with an example of the present disclosure.

FIG. 12B is a diagram illustrating a three-dimensional view of a multi-functional optical module integrated together and illustrates a rear view of a printed circuit board assembly LED driver connected to the multi-functional optical module in accordance with an example of the present disclosure.

FIG. 13 is a diagram illustrating a portion of smart glasses including cameras in accordance with an example of the present disclosure.

FIG. 14 illustrates an operation of an exemplary process in accordance with examples of the present disclosure.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

For simplicity and illustrative purposes, the present application is described by referring mainly to examples thereof. In the following description, numerous specific details are set forth in order to provide a thorough understanding of the present application. It will be readily apparent, however, that the present application may be practiced without limitation to these specific details. In other instances, some methods and structures readily understood by one of ordinary skill in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on.

Eye-tracking may be used in some head-mounted display (HMD) devices. Some eye-tracking techniques are image-based and use near-infrared (nIR) illumination sources and cameras to track pupil and corneal reflections (e.g., glints). These reflections may be used to determine the direction of the user's gaze. To reduce the gaze error, it may be important to generate enough separated bright glints from inside the spherical region of the cornea close to the pupil center at a variety of possible gaze directions (e.g., ideally, all possible gaze directions).

To promote utility, it is desirable for an eye-tracking system to be able to detect gaze direction accurately for a broad population with a variety of eye shapes, eye sizes, head shapes, and head sizes, as well as different degrees of vision impairment. It is also desirable for an eye-tracking system to detect gaze direction accurately across a variety of use cases or scenarios. It is important for components of an eye-tracking system to balance system design criteria, such as low power consumption, size, weight, reliability, manufacturability, and cost.

Disclosed herein are systems, methods, and apparatuses that may use an optical assembly (OSM) with integrated near infrared (nIR) micro light emitting diodes (LEDs) for eye-tracking applications. The optical assembly may be cut into the shape of an eye opening using a laser trimming process. Using near infrared (nIR) micro light emitting diodes for illumination may simplify the architecture of the eye-tracking system and reduce manufacturing costs. In addition, the need to use a laser for eye tracking may be reduced or eliminated.

According to various examples, an eye-tracking system may include an optical assembly with integrated micro light emitting diodes. The optical assembly may include a substrate and a flexible printed circuit board assembly bonded to the substrate. Micro light emitting diodes may also be bonded to the substrate. A plurality of electrical conductors may be patterned on the substrate. The electrical conductors may electrically connect the micro light emitting diodes to the printed circuit board assembly. An optically clear adhesive layer may be adhered to the substrate. The optically clear adhesive layer may include an anti-reflective layer and an optical adhesive layer arranged in a stacked configuration. The eye-tracking system may be incorporated into a head-mounted display (HMD) device.

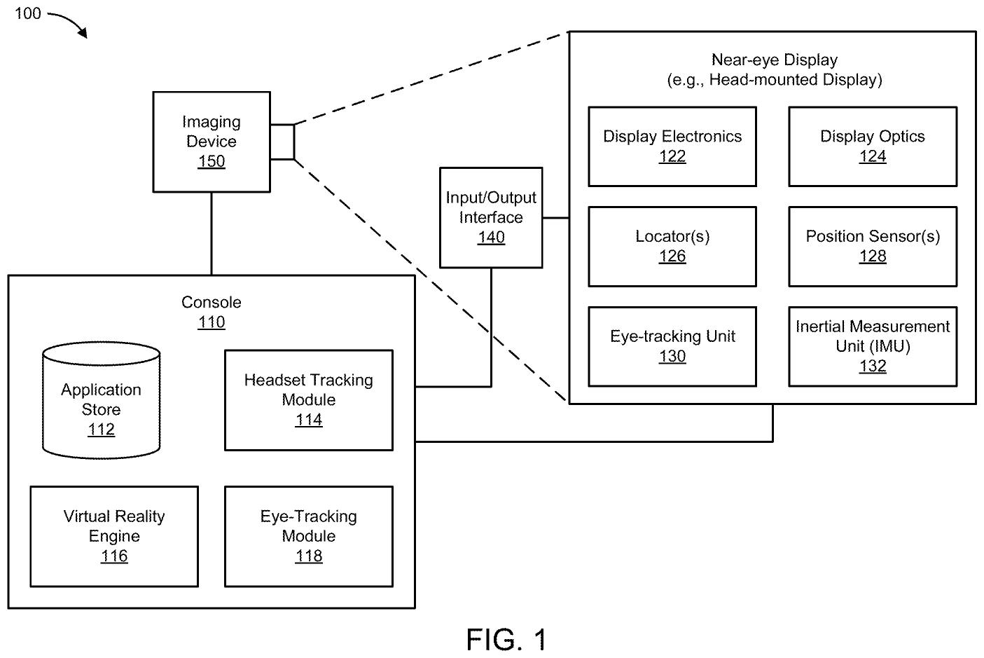

FIG. 1 illustrates a block diagram of an artificial reality system environment 100 including a near-eye display, according to an example. As used herein, a “near-eye display” may refer to a device (e.g., an optical device) that may be in close proximity to a user's eye. As used herein, “artificial reality” may refer to aspects of, among other things, a “metaverse” or an environment of real and virtual elements, and may include use of technologies associated with virtual reality (VR), augmented reality (AR), and/or mixed reality (MR). As used herein a “user” may refer to a user or wearer of a “near-eye display.”

As shown in FIG. 1, the artificial reality system environment 100 may include a near-eye display 120, an optional external imaging device 150, and an optional input/output interface 140, each of which may be coupled to a console 110. The console 110 may be optional in some instances as the functions of the console 110 may be integrated into the near-eye display 120. In some examples, the near-eye display 120 may be a head-mounted display (HMD) that presents content to a user.

In some instances, for a near-eye display system, it may generally be desirable to expand an eye box, reduce display haze, improve image quality (e.g., resolution and contrast), reduce physical size, increase power efficiency, and increase or expand field of view (FOV). As used herein, “field of view” (FOV) may refer to an angular range of an image as seen by a user, which is typically measured in degrees as observed by one eye (for a monocular HMD) or both eyes (for binocular HMDs). Also, as used herein, an “eye box” may be a two-dimensional box that may be positioned in front of the user's eye from which a displayed image from an image source may be viewed.

In some examples, in a near-eye display system, light from a surrounding environment may traverse a “see-through” region of a waveguide display (e.g., a transparent substrate) to reach a user's eyes. For example, in a near-eye display system, light of projected images may be coupled into a transparent substrate of a waveguide, propagate within the waveguide, and be coupled or directed out of the waveguide at one or more locations to replicate exit pupils and expand the eye box.

In some examples, the near-eye display 120 may include one or more rigid bodies, which may be rigidly or non-rigidly coupled to each other. In some examples, a rigid coupling between rigid bodies may cause the coupled rigid bodies to act as a single rigid entity, while in other examples, a non-rigid coupling between rigid bodies may allow the rigid bodies to move relative to each other.

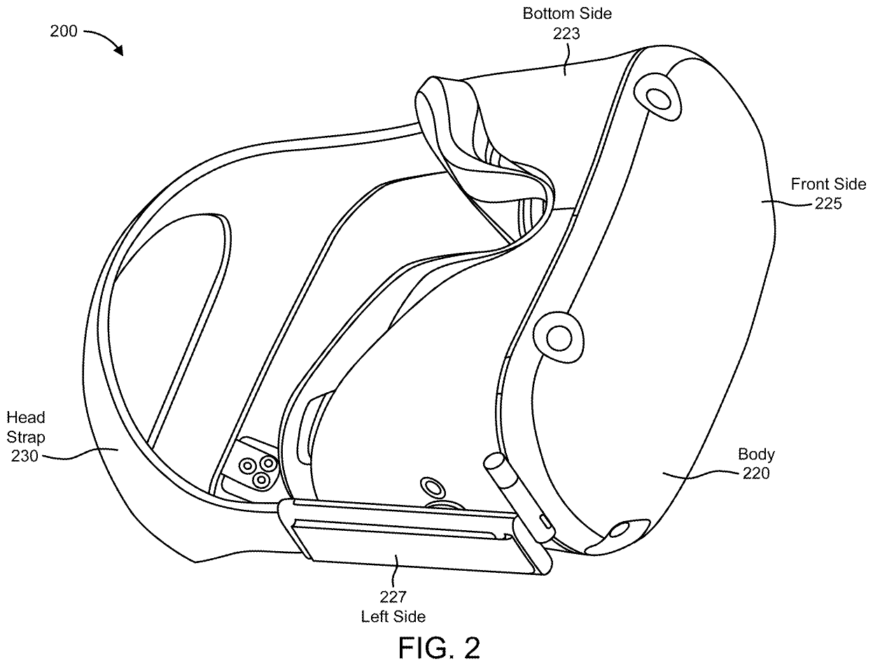

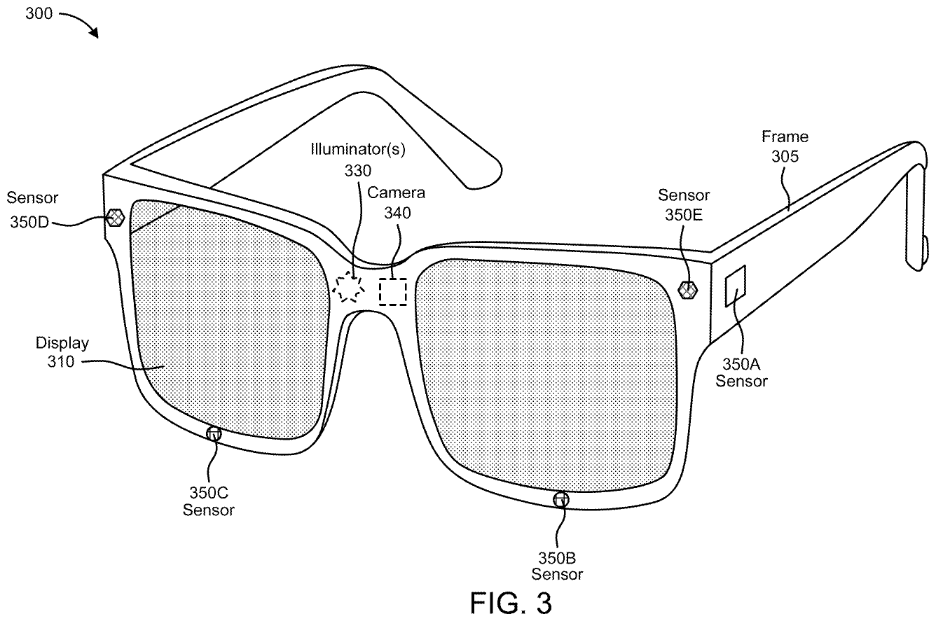

In some examples, the near-eye display 120 may be implemented in any suitable form-factor, including an HMD, a pair of glasses, or other similar wearable eyewear or device. Examples of the near-eye display 120 are further described below with respect to FIGS. 2 and 3. Additionally, in some examples, the functionality described herein may be used in an HMD or headset that may combine images of an environment external to the near-eye display 120 and artificial reality content (e.g., computer-generated images). Therefore, in some examples, the near-eye display 120 may augment images of a physical, real-world environment external to the near-eye display 120 with generated and/or overlaid digital content (e.g., images, video, sound, etc.) to present an augmented reality to a user.

In some examples, the near-eye display 120 may include any number of display electronics 122, display optics 124, and an eye-tracking unit 130. In some examples, the near eye display 120 may also include one or more locators 126, one or more position sensors 128, and an inertial measurement unit (IMU) 132. In some examples, the near-eye display 120 may omit any of the eye-tracking unit 130, the one or more locators 126, the one or more position sensors 128, and the inertial measurement unit (IMU) 132, or may include additional elements.

In some examples, the display electronics 122 may display or facilitate the display of images to the user according to data received from, for example, the optional console 110. In some examples, the display electronics 122 may include one or more display panels. In some examples, the display electronics 122 may include any number of pixels to emit light of a predominant color such as red, green, blue, white, or yellow. In some examples, the display electronics 122 may display a three-dimensional (3D) image, e.g., using stereoscopic effects produced by two-dimensional panels, to create a subjective perception of image depth.

In some examples, the display optics 124 may display image content optically (e.g., using optical waveguides and/or couplers) or magnify image light received from the display electronics 122, correct optical errors associated with the image light, and/or present the corrected image light to a user of the near-eye display 120. In some examples, the display optics 124 may include a single optical element or any number of combinations of various optical elements as well as mechanical couplings to maintain relative spacing and orientation of the optical elements in the combination. In some examples, one or more optical elements in the display optics 124 may have an optical coating, such as an anti-reflective coating, a reflective coating, a filtering coating, and/or a combination of different optical coatings.

In some examples, the display optics 124 may also be designed to correct one or more types of optical errors, such as two-dimensional optical errors, three-dimensional optical errors, or any combination thereof. Examples of two-dimensional errors may include barrel distortion, pincushion distortion, longitudinal chromatic aberration, and/or transverse chromatic aberration. Examples of three-dimensional errors may include spherical aberration, chromatic aberration field curvature, and astigmatism.

In some examples, the one or more locators 126 may be objects located in specific positions relative to one another and relative to a reference point on the near-eye display 120. In some examples, the optional console 110 may identify the one or more locators 126 in images captured by the optional external imaging device 150 to determine the artificial reality headset's position, orientation, or both. The one or more locators 126 may each be a light-emitting diode (LED), a corner cube reflector, a reflective marker, a type of light source that contrasts with an environment in which the near-eye display 120 operates, or any combination thereof.

In some examples, the external imaging device 150 may include one or more cameras, one or more video cameras, any other device capable of capturing images including the one or more locators 126, or any combination thereof. The optional external imaging device 150 may be configured to detect light emitted or reflected from the one or more locators 126 in a field of view of the optional external imaging device 150.

In some examples, the one or more position sensors 128 may generate one or more measurement signals in response to motion of the near-eye display 120. Examples of the one or more position sensors 128 may include any number of accelerometers, gyroscopes, magnetometers, and/or other motion-detecting or error-correcting sensors, or any combination thereof.

In some examples, the inertial measurement unit (IMU) 132 may be an electronic device that generates fast calibration data based on measurement signals received from the one or more position sensors 128. The one or more position sensors 128 may be located external to the inertial measurement unit (IMU) 132, internal to the inertial measurement unit (IMU) 132, or any combination thereof. Based on the one or more measurement signals from the one or more position sensors 128, the inertial measurement unit (IMU) 132 may generate fast calibration data indicating an estimated position of the near-eye display 120 that may be relative to an initial position of the near-eye display 120. For example, the inertial measurement unit (IMU) 132 may integrate measurement signals received from accelerometers over time to estimate a velocity vector and integrate the velocity vector over time to determine an estimated position of a reference point on the near-eye display 120. Alternatively, the inertial measurement unit (IMU) 132 may provide the sampled measurement signals to the optional console 110, which may determine the fast calibration data.

The eye-tracking unit 130 may include one or more eye-tracking systems. As used herein, “eye tracking” may refer to determining an eye's position or relative position, including orientation, location, and/or gaze of a user's eye. In some examples, an eye-tracking system may include an imaging system that captures one or more images of an eye and may optionally include a light emitter, which may generate light that is directed to an eye such that light reflected by the eye may be captured by the imaging system. In other examples, the eye-tracking unit 130 may capture reflected radio waves emitted by a miniature radar unit. These data associated with the eye may be used to determine or predict eye position, orientation, movement, location, and/or gaze.

In some examples, the near-eye display 120 may use the orientation of the eye to introduce depth cues (e.g., blur image outside of the user's main line of sight), collect heuristics on the user interaction in the virtual reality (VR) media (e.g., time spent on any particular subject, object, or frame as a function of exposed stimuli), some other functions that are based in part on the orientation of at least one of the user's eyes, or any combination thereof. In some examples, because the orientation may be determined for both eyes of the user, the eye-tracking unit 130 may be able to determine where the user is looking or predict any user patterns, etc.

In some examples, the input/output interface 140 may be a device that allows a user to send action requests to the optional console 110. As used herein, an “action request” may be a request to perform a particular action. For example, an action request may be to start or to end an application or to perform a particular action within the application. The input/output interface 140 may include one or more input devices. Example input devices may include a keyboard, a mouse, a game controller, a glove, a button, a touch screen, or any other suitable device for receiving action requests and communicating the received action requests to the optional console 110. In some examples, an action request received by the input/output interface 140 may be communicated to the optional console 110, which may perform an action corresponding to the requested action.

In some examples, the optional console 110 may provide content to the near-eye display 120 for presentation to the user in accordance with information received from one or more of external imaging device 150, the near-eye display 120, and the input/output interface 140. For example, in the example shown in FIG. 1, the optional console 110 may include an application store 112, a headset tracking module 114, a virtual reality engine 116, and an eye-tracking module 118. Some examples of the optional console 110 may include different or additional modules than those described in conjunction with FIG. 1. Functions further described below may be distributed among components of the optional console 110 in a different manner than is described here.

In some examples, the optional console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In some examples, the modules of the optional console 110 described in conjunction with FIG. 1 may be encoded as instructions in the non-transitory computer-readable storage medium that, when executed by the processor, cause the processor to perform the functions further described below. It should be appreciated that the optional console 110 may or may not be needed or the optional console 110 may be integrated with or separate from the near-eye display 120.

In some examples, the application store 112 may store one or more applications for execution by the optional console 110. An application may include a group of instructions that, when executed by a processor, generates content for presentation to the user. Examples of the applications may include gaming applications, conferencing applications, video playback application, or other suitable applications.

In some examples, the headset tracking module 114 may track movements of the near-eye display 120 using slow calibration information from the external imaging device 150. For example, the headset tracking module 114 may determine positions of a reference point of the near-eye display 120 using observed locators from the slow calibration information and a model of the near-eye display 120. Additionally, in some examples, the headset tracking module 114 may use portions of the fast calibration information, the slow calibration information, or any combination thereof, to predict a future location of the near-eye display 120. In some examples, the headset tracking module 114 may provide the estimated or predicted future position of the near-eye display 120 to the virtual reality engine 116.

In some examples, the virtual reality engine 116 may execute applications within the artificial reality system environment 100 and receive position information of the near-eye display 120, acceleration information of the near-eye display 120, velocity information of the near-eye display 120, predicted future positions of the near-eye display 120, or any combination thereof from the headset tracking module 114. In some examples, the virtual reality engine 116 may also receive estimated eye position and orientation information from the eye-tracking module 118. Based on the received information, the virtual reality engine 116 may determine content to provide to the near-eye display 120 for presentation to the user.

In some examples, the eye-tracking module 118 may receive eye-tracking data from the eye-tracking unit 130 and determine the position of the user's eye based on the eye tracking data. In some examples, the position of the eye may include an eye's orientation, location, or both relative to the near-eye display 120 or any element thereof. So, in these examples, because the eye's axes of rotation change as a function of the eye's location in its socket, determining the eye's location in its socket may allow the eye-tracking module 118 to more accurately determine the eye's orientation.

In some examples, a location of a projector of a display system may be adjusted to enable any number of design modifications. For example, in some instances, a projector may be located in front of a viewer's eye (i.e., “front-mounted” placement). In a front-mounted placement, in some examples, a projector of a display system may be located away from a user's eyes (i.e., “world-side”). In some examples, a head-mounted display (HMD) device may utilize a front-mounted placement to propagate light towards a user's eye(s) to project an image.

FIG. 2 illustrates a perspective view of a near-eye display in the form of a head-mounted display (HMD) device 200, according to an example. In some examples, the HMD device 200 may be a part of a virtual reality (VR) system, an augmented reality (AR) system, a mixed reality (MR) system, another system that uses displays or wearables, or any combination thereof. In some examples, the HMD device 200 may include a body 220 and a head strap 230. FIG. 2 shows a bottom side 223, a front side 225, and a left side 227 of the body 220 in the perspective view. In some examples, the head strap 230 may have an adjustable or extendible length. In particular, in some examples, there may be a sufficient space between the body 220 and the head strap 230 of the HMD device 200 for allowing a user to mount the HMD device 200 onto the user's head. For example, the length of the head strap 230 may be adjustable to accommodate a range of user head sizes. In some examples, the HMD device 200 may include additional, fewer, and/or different components.

In some examples, the HMD device 200 may present, to a user, media or other digital content including virtual and/or augmented views of a physical, real-world environment with computer-generated elements. Examples of the media or digital content presented by the HMD device 200 may include images (e.g., two-dimensional (2D) or three-dimensional (3D) images), videos (e.g., 2D or 3D videos), audio, or any combination thereof. In some examples, the images and videos may be presented to each eye of a user by one or more display assemblies (not shown in FIG. 2) enclosed in the body 220 of the HMD device 200.

In some examples, the HMD device 200 may include various sensors (not shown), such as depth sensors, motion sensors, position sensors, and/or eye tracking sensors. Some of these sensors may use any number of structured or unstructured light patterns for sensing purposes. In some examples, the HMD device 200 may include an input/output interface 140 for communicating with a console 110, as described with respect to FIG. 1. In some examples, the HMD device 200 may include a virtual reality engine (not shown), but similar to the virtual reality engine 116 described with respect to FIG. 1, that may execute applications within the HMD device 200 and receive depth information, position information, acceleration information, velocity information, predicted future positions, or any combination thereof of the HMD device 200 from the various sensors.

In some examples, the information received by the virtual reality engine 116 may be used for producing a signal (e.g., display instructions) to the one or more display assemblies. In some examples, the HMD device 200 may include locators (not shown), but similar to the virtual locators 126 described in FIG. 1, which may be located in fixed positions on the body 220 of the HMD device 200 relative to one another and relative to a reference point. Each of the locators may emit light that is detectable by an external imaging device. This may be useful for the purposes of head tracking or other movement/orientation. It should be appreciated that other elements or components may also be used in addition or in lieu of such locators.

It should be appreciated that in some examples, a projector mounted in a display system may be placed near and/or closer to a user's eye (i.e., “eye-side”). In some examples, and as discussed herein, a projector for a display system shaped liked eyeglasses may be mounted or positioned in a temple arm (i.e., a top far corner of a lens side) of the eyeglasses. It should be appreciated that, in some instances, utilizing a back-mounted projector placement may help to reduce size or bulkiness of any required housing required for a display system, which may also result in a significant improvement in user experience for a user.

FIG. 3 is a perspective view of a near-eye display 300 in the form of a pair of glasses (or other similar eyewear), according to an example. In some examples, the near-eye display 300 may be a specific example of near-eye display 120 of FIG. 1, and may be configured to operate as a virtual reality display, an augmented reality display, and/or a mixed reality display.

In some examples, the near-eye display 300 may include a frame 305 and a display 310. In some examples, the display 310 may be configured to present media or other content to a user. In some examples, the display 310 may include display electronics and/or display optics, similar to components described with respect to FIGS. 1-2. For example, as described above with respect to the near-eye display 120 of FIG. 1, the display 310 may include a liquid crystal display (LCD) display panel, a light-emitting diode (LED) display panel, or an optical display panel (e.g., a waveguide display assembly). In some examples, the display 310 may also include any number of optical components, such as waveguides, gratings, lenses, mirrors, etc.

In some examples, the near-eye display 300 may further include various sensors 350a, 350b, 350c, 350d, and 350e on or within a frame 305. In some examples, the various sensors 350a-350e may include any number of depth sensors, motion sensors, position sensors, inertial sensors, and/or ambient light sensors, as shown. In some examples, the various sensors 350a-350e may include any number of image sensors configured to generate image data representing different fields of views in one or more different directions. In some examples, the various sensors 350a-350e may be used as input devices to control or influence the displayed content of the near-eye display 300, and/or to provide an interactive virtual reality (VR), augmented reality (AR), and/or mixed reality (MR) experience to a user of the near-eye display 300. In some examples, the various sensors 350a-350e may also be used for stereoscopic imaging or other similar application.

In some examples, the near-eye display 300 may further include one or more illuminators 330 to project light into a physical environment. The projected light may be associated with different frequency bands (e.g., visible light, infra-red light, ultra-violet light, etc.), and may serve various purposes. In some examples, the one or more illuminator(s) 330 may be used as locators, such as the one or more locators 126 described above with respect to FIGS. 1-2.

In some examples, the near-eye display 300 may also include a camera 340 or other image capture unit. The camera 340, for instance, may capture images of the physical environment in the field of view. In some instances, the captured images may be processed, for example, by a virtual reality engine (e.g., the virtual reality engine 116 of FIG. 1) to add virtual objects to the captured images or modify physical objects in the captured images, and the processed images may be displayed to the user by the display 310 for augmented reality (AR) and/or mixed reality (MR) applications.

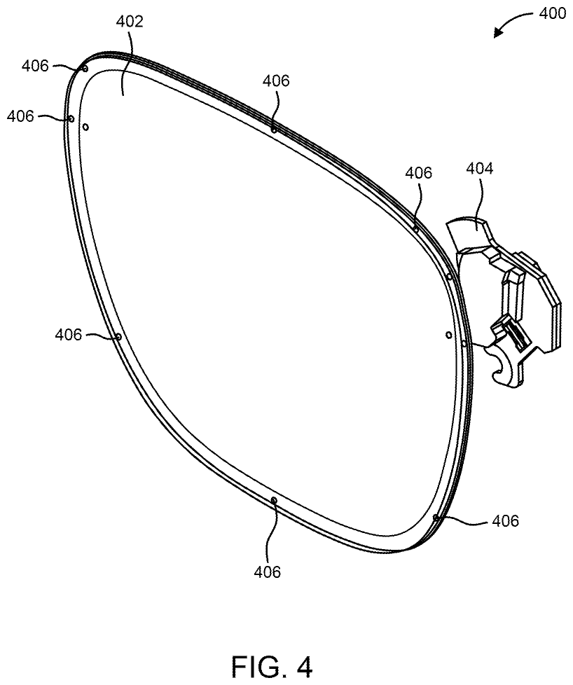

FIG. 4 illustrates a perspective view of an optical assembly 400 with bonded micro light emitting diodes, in accordance with various examples. In some examples, other illumination sources may be used. For example, lasers, such as vertical cavity surface emitting lasers (VCSELs) may be used as illumination sources. VCSELs coupled with photonic integrated waveguides may be used as illumination sources. The optical assembly 400 may be integrated as part of a head-mounted display (HMD) device, such as the near-eye display 300 of FIG. 3. In some examples, the optical assembly 400 may include an L1 layer 402. The L1 layer 402 may be implemented as a rigid, transparent substrate that provides a mechanical support for a flexible film substrate with light emitting diodes (LEDs) or other illumination sources. The L1 layer 402 may be formed from glass or another suitable material. In some examples, the L1 layer 402, which may also be referred to as a virtual image distance (VID) layer, may control a perceived distance of a displayed image. For example, by controlling the phase of light passing through the L1 layer 402 that is associated with a displayed image, the L1 layer 402 may cause the image to appear in front of or behind objects in a physical environment.

In some examples, the optical assembly 400 includes a printed circuit board assembly (PCBA) 404. The printed circuit board assembly 404 may provide an interface between the optical assembly 400 and other components of the head-mounted display (HMD) device. For example, the printed circuit board assembly 404 may communicate data and/or control signals between the optical assembly 400 and other components, such as control circuitry. As another example, the printed circuit board assembly 404 may conduct power from a power source, such as a battery, to the optical assembly 400.

In some examples, the printed circuit board assembly 404 is bonded to a substrate. For example, anisotropic conductive bonding (ACF), wire bonding, or other suitable techniques may be used to connect the printed circuit board assembly 404 to the conductive patterns on the substrate. Anisotropic conductive bonding, for example, may be used to connect illumination or display circuit patterns to a printed circuit board using anisotropic conductive adhesive and flex coils. This may provide a low-cost manufacturing process to interconnect multiple dense conductive traces. Anisotropic conductive bonding may enable electrical conductivity in one direction (e.g., vertical), but not another (e.g., lateral) after the high pressure and temperature process is completed. The substrate may be formed from a transparent material, such as glass, transparent polyimide, polyethylene terephthalate (PET), PEN, polycarbonate, cyclo-olefin polymer (COP), PMMA, polyvinyl chloride (PVC), and the like. The printed circuit board assembly 404 may be bonded to the substrate using anisotropic conductive film.

In some examples, micro light emitting diodes (LEDs) 406 (e.g., more than six micro LEDs) are bonded onto the substrate. For example, as illustrated in FIG. 4, the micro light emitting diodes 406 may be located around the perimeter of the substrate. The micro light emitting diodes 406 may have dimensions (e.g., length and/or width) less than 250 μm. In some examples, the micro light emitting diodes 406 may have a peak wavelength output in the range of 930 nm to 950 nm, with a spectral width (full width at half maximum (FWHM)) of 20-50 nm. The micro light emitting diodes 406 may have a radiant flux greater than 2 mW with an emission cone angle greater than 60° and a wall plug efficiency (WPE) greater than 5%.

The micro light emitting diodes 406 may be electrically connected to the printed circuit board assembly 404 via electrical conductors. For example, conductive (e.g., copper) wires may be laminated or otherwise integrated in the substrate. In some examples, a thin (e.g., 1-2 microns) seed layer including nickel and/or copper may be deposited via a plating or vacuum sputtering process. A modified semi-additive process (mSAP) may be used to pattern and coat a thicker (e.g., 10-20 microns) copper layer and a protective metal layer on the seed layer. The protective layer may include, for example, nickel, palladium, and/or gold layers, each of which may be 0.5-2 microns thick. A rigid glass layer with a thermal debonding film (TDF) layer may be applied on the back of the flexible printed circuit board assembly 404 for further steps of applying the micro light emitting diodes 406 via a bonding process, cutting eye shapes, and/or laminating printed circuit board connectors to connect the conductive traces. In some examples, transparent conductive electrodes may electrically connect the micro light emitting diodes 406 to the printed circuit board assembly 404. The transparent conductive electrodes may be sputtered onto a substrate and then patterned into isolated conductive traces. The conductive electrodes may be formed from indium doped tin oxide, aluminum doped zinc oxide, silver nanowires, nano-fiber meshes and/or polymeric materials with metal conductive traces, for example. As another example, the conductive electrodes may be formed from copper mesh lines comprising small copper lines separated by gaps. In some examples, the micro light emitting diodes and/or conductive traces may be encapsulated by an adhesive and/or another material. This material may also seal the edge of the optical assembly 400.

In some examples, an optically clear adhesive (OCA) layer may be located between the L1 layer 402 and the substrate. The optically clear adhesive layer may include a stack of anti-reflective layers and optical adhesive layers, e.g., arranged in an interleaved configuration. The stack of anti-reflective layers and optical adhesive layers may enable a total optical transmission exceeding 90% in the visible spectrum. In some examples, a side of the optically clear adhesive layer that faces the user's eye may have an anti-reflective coating that is characterized by a reflection of less than 10% at all angles of incidence less than 60°. In some examples, the optically clear adhesive layer may reduce the appearance of artifacts in the displayed image.

In some examples, a virtual imaging distance (VID1) lens element may be located on a side of the optical assembly 400 that faces the user's eye. The virtual imaging distance lens element may add a refractive power to adjust the perceived distance of a displayed image, for example, to accommodate users who use a head-mounted display (HMD) device with corrective lenses. For example, the L1 layer 402 on the world side may include a refractive power of, e.g., −0.65 diopter, which will bring the virtual image distance to, e.g., 1.5 m to provide high visual acuity for users. To correct the virtual imaging distance effect on the world side, another virtual imaging distance (e.g., VID1) layer having a refractive power of, e.g., −0.65 diopter may be included to compensate for the refractive power of the L1 layer 402. For users with myopia, then in addition to the −0.65 diopter with the L1 layer 402, an extra optical power may be integrated with the VID1 layer. The strength of the optical power may depend on the user's prescription.

In some examples, the optical assembly 400 may include one or more waveguide elements to direct a displayed image toward the user's eyes. The waveguide elements may be implemented in a layer located, for example, inward from a second virtual imaging distance (VID2) lens element, described herein.

In some examples, the optical assembly 400 may include a second virtual imaging distance (VID2) lens element. The second virtual imaging distance (VID2) lens element may be located on a world-facing side of the optical assembly 400. In some examples, the second virtual imaging distance (VID2) lens element has a refractive power, e.g., to compensate for a virtual imaging distance change introduced by another virtual imaging distance lens element. For example, the second virtual imaging distance lens element may have a spherical refractive power of +0.65 diopter. This may allow the user to see through the optical assembly correctly. In some examples, the second virtual imaging distance (VID2) lens element may provide variable visible transmission in the presence of ambient light to control the display contrast. This may facilitate use of the optical assembly 400 in both indoor and outdoor environments, e.g., with a dimmer. The second virtual imaging distance (VID2) lens element may be able to selectively control the amount of light that is passed through from the outside environment to promote consistency of the display contrast. In some examples, the second virtual imaging distance (VID2) lens element provides protection against environmental pollution, damage, and wear and tear associated with usage.

In some examples, the optical assembly 400 may include a holographic optical element (HOE). The holographic optical element may diffract near infrared (nIR) light from the eye reflection (e.g., glint) toward an optical sensor. Using the holographic optical element may result in faster stereo view calibration for eye-tracking, as well as faster eye-tracking authentication.

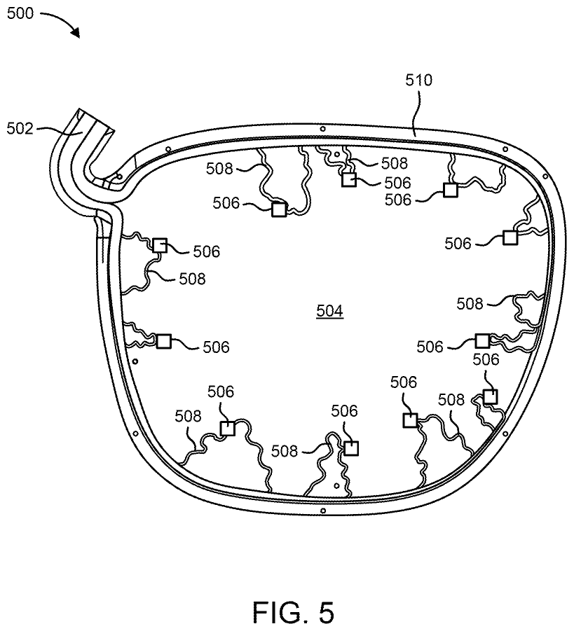

FIG. 5 illustrates a plan view of an optical assembly 500 with bonded micro light emitting diodes, in accordance with various examples. The optical assembly 500 may include a printed circuit board assembly (PCBA) 502 that provides an interface between the optical assembly 500 and other components of the head-mounted display (HMD) device. For example, the printed circuit board assembly 502 may communicate data and/or control signals between the optical assembly 500 and other components, such as control circuitry. As another example, the printed circuit board assembly 502 may conduct power from a power source, such as a battery, to the optical assembly 500.

In some examples, the printed circuit board assembly 502 is bonded to a patterned substrate 504. The patterned substrate 504 may be formed from a transparent material, such as glass, transparent polyimide, polyethylene terephthalate (PET), PEN, polycarbonate, cyclo-olefin polymer (COP), PMMA, polyvinyl chloride (PVC), and the like. In some examples, the patterned substrate 504 includes electrical conductors, e.g., conductive traces or smaller conductors, arranged on the surface or under the surface to form a pattern. The printed circuit board assembly 502 may be bonded to the patterned substrate 504 using anisotropic conductive film.

In some examples, micro light emitting diodes (LEDs) 506 (e.g., more than six micro LEDs) are bonded onto the patterned substrate 504. As illustrated in FIG. 5, the micro light emitting diodes 506 may be located in an interior region of the patterned substrate 504. Locating the micro light emitting diodes 506 in an interior region of the patterned substrate 504 may provide more uniform illumination in the eye box. As a result, when a strong refractive power is integrated for vision correction, illumination may be more uniform. In addition, shorter eye-relief distances may be realized because the light from the micro light emitting diodes 506 may travel a shorter distance to the user's eye. The micro light emitting diodes 506 may have dimensions (e.g., length and/or width) less than 250 μm. In some examples, the micro light emitting diodes 506 may have a peak wavelength output in the range of 930 nm to 950 nm, with a spectral width (full width at half maximum (FWHM)) of 20-50 nm. The micro light emitting diodes 506 may have a radiant flux greater than 2 mW with an emission cone angle greater than 60° and a wall plug efficiency (WPE) greater than 5%.

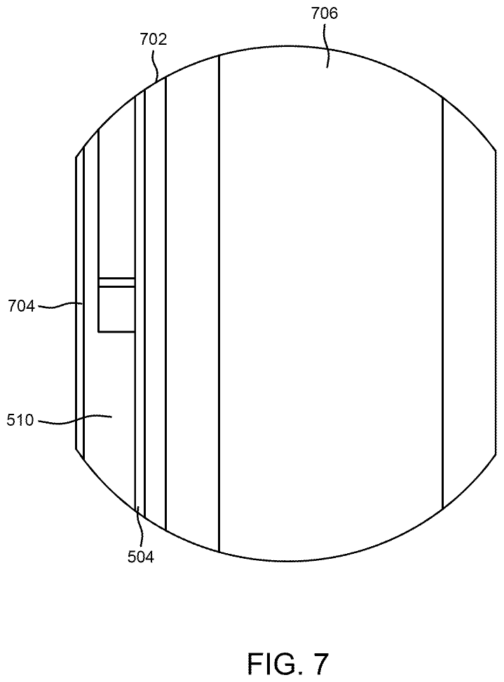

The micro light emitting diodes 506 may be electrically connected to the printed circuit board assembly 502 via electrical conductors 508. For example, conductive (e.g., copper) wires may be laminated or otherwise integrated in the substrate. In some examples, a thin (e.g., 1-2 microns) seed layer including nickel and/or copper may be deposited via a plating or vacuum sputtering process. A modified semi-additive process (mSAP) may be used to pattern and coat a thicker (e.g., 10-20 microns) copper layer and a protective metal layer on the seed layer. The protective layer may include, for example, nickel, palladium, and/or gold layers, each of which may be 0.5-2 microns thick. A rigid glass layer with a thermal debonding film (TDF) layer may be applied on the back of the printed circuit board assembly 502 for further steps of applying the micro light emitting diodes 506 via a bonding process, cutting eye shapes, and/or laminating printed circuit board connectors to connect the conductive traces. In some examples, transparent conductive electrodes may electrically connect the micro light emitting diodes 506 to the printed circuit board assembly 502. The transparent conductive electrodes may be sputtered onto a substrate and then patterned into isolated conductive traces. The conductive electrodes may be formed from indium doped tin oxide, aluminum doped zinc oxide, silver nanowires, nano-fiber meshes and/or polymeric materials with metal conductive traces, for example. As another example, the conductive electrodes may be formed from copper mesh lines comprising small copper lines separated by gaps. In some examples, the micro light emitting diodes and/or conductive traces may be encapsulated by an adhesive and/or another encapsulating material 510. This encapsulating material 510 may also seal the edge of the optical assembly 500. FIG. 7 illustrates a cross sectional view of the patterned substrate 504, the encapsulating material 510, a thermal debonding film 702, a protective film 704, and a glass carrier 706. The glass carrier 706 may be removed after the optical assembly 500 has been manufactured.

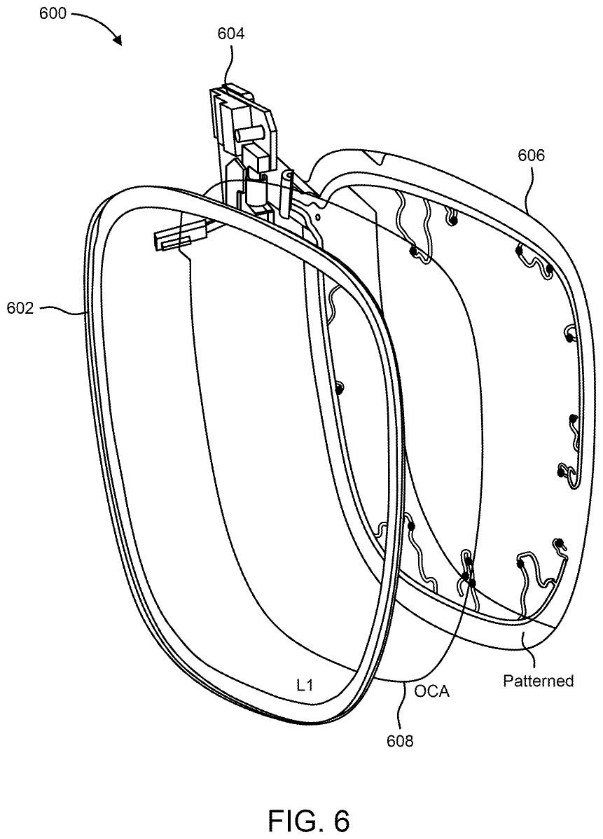

FIG. 6 illustrates an expanded view of an optical assembly 600 with bonded micro light emitting diodes, in accordance with various examples. In some examples, other illumination sources may be used. For example, lasers, such as vertical cavity surface emitting lasers (VCSELs) may be used as illumination sources. VCSELs coupled with photonic integrated waveguides may be used as illumination sources. The optical assembly 600 may be integrated as part of a head-mounted display (HMD) device, such as the near-eye display 300 of FIG. 3. In some examples, the optical assembly 600 may include an L1 layer 602. The L1 layer 602 may be implemented as a rigid, transparent substrate that provides a mechanical support for a flexible film substrate with light emitting diodes (LEDs) or other illumination sources. The L1 layer 602 may be formed from glass or another suitable material. In some examples, the L1 layer 602, which may also be referred to as a virtual image distance (VID) layer, may control a perceived distance of a displayed image. For example, by controlling the phase of light passing through the L1 layer 602 that is associated with a displayed image, the L1 layer 602 may cause the image to appear in front of or behind objects in a physical environment.

In some examples, the optical assembly 600 includes a printed circuit board assembly (PCBA) 604. The printed circuit board assembly 604 may provide an interface between the optical assembly 600 and other components of the head-mounted display (HMD) device. For example, the printed circuit board assembly 604 may communicate data and/or control signals between the optical assembly 600 and other components, such as control circuitry. As another example, the printed circuit board assembly 604 may conduct power from a power source, such as a battery, to the optical assembly 600.

In some examples, the printed circuit board assembly 604 is bonded to a substrate 606. The substrate 606 may be formed from a transparent material, such as glass, transparent polyimide, polyethylene terephthalate (PET), PEN, polycarbonate, cyclo-olefin polymer (COP), PMMA, polyvinyl chloride (PVC, and the like. The printed circuit board assembly 604 may be bonded to the substrate 606 using anisotropic conductive film.

In some examples, micro light emitting diodes (LEDs) (e.g., more than six micro LEDs) are bonded onto the substrate 606. The micro light emitting diodes may have dimensions (e.g., length and/or width) less than 250 μm. In some examples, the micro light emitting diodes may have a peak wavelength output in the range of 930 nm to 950 nm, with a spectral width (full width at half maximum (FWHM)) of 20-50 nm. The micro light emitting diodes may have a radiant flux greater than 2 mW with an emission cone angle greater than 60° and a wall plug efficiency (WPE) greater than 5%.

The micro light emitting diodes may be electrically connected to the printed circuit board assembly 604 via electrical conductors. For example, conductive (e.g., copper) wires may be laminated or otherwise integrated in the substrate 606. In some examples, transparent conductive electrodes may electrically connect the micro light emitting diodes to the printed circuit board assembly 604. In some examples, a thin (e.g., 1-2 microns) seed layer including nickel and/or copper may be deposited via a plating or vacuum sputtering process. A modified semi-additive process (mSAP) may be used to pattern and coat a thicker (e.g., 10-20 microns) copper layer and a protective metal layer on the seed layer. The protective layer may include, for example, nickel, palladium, and/or gold layers, each of which may be 0.5-2 microns thick. A rigid glass layer with a thermal debonding film (TDF) layer may be applied on the back of the flexible printed circuit board assembly 604 for further steps of applying the micro light emitting diodes via a bonding process, cutting eye shapes, and/or laminating printed circuit board connectors to connect the conductive traces. The conductive electrodes may be formed from indium doped tin oxide, aluminum doped zinc oxide, silver nanowires, nano-fiber meshes and/or polymeric materials with metal conductive traces, for example. As another example, the conductive electrodes may be formed from copper mesh lines comprising small copper lines separated by gaps. In some examples, the micro light emitting diodes and/or conductive traces may be encapsulated by an adhesive and/or another material. This material may also seal the edge of the optical assembly 600.

In some examples, an optically clear adhesive (OCA) layer 608 may be located between the L1 layer 602 and the substrate 606. The optically clear adhesive layer 608 may include a stack of anti-reflective layers and optical adhesive layers. The stack of layers may enable a total optical transmission exceeding 90% in the visible spectrum. In some examples, a side of the optically clear adhesive layer 608 that faces the user's eye may have an anti-reflective coating that is characterized by a reflection of less than 10% at all angles of incidence less than 60°. In some examples, the optically clear adhesive layer 608 may reduce the appearance of artifacts in the displayed image.

In some examples, a virtual imaging distance (VID1) lens element may be located on a side of the optical assembly 600 that faces the user's eye. The virtual imaging distance lens element may add a refractive power to adjust the perceived distance of a displayed image, for example, to accommodate users who use a head-mounted display (HMD) device with corrective lenses. For example, the L1 layer 602 on the world side may include a refractive power of, e.g., −0.65 diopter, which will bring the virtual image distance to, e.g., 1.5 m to provide high visual acuity for users. To correct the virtual imaging distance effect on the world side, another virtual imaging distance (e.g., VID1) layer having a refractive power of, e.g., +0.65 diopter may be included to compensate for the refractive power of the L1 layer 602. For users with myopia, then in addition to the −0.65 diopter with the L1 layer 602, an extra optical power may be integrated with the VID1 layer. The strength of the optical power may depend on the user's prescription.

In some examples, the optical assembly 600 may include one or more waveguide elements to direct a displayed image toward the user's eyes. The waveguide elements may be implemented in a layer located, for example, inward from a second virtual imaging distance (VID2) lens element, described herein.

In some examples, the optical assembly 600 may include a second virtual imaging distance (VID2) lens element having a refractive power. The second virtual imaging distance (VID2) lens element may be located on a world-facing side of the optical assembly 600. In some examples, the second virtual imaging distance (VID2) lens element may have a refractive power, e.g., to compensate for a virtual imaging distance change introduced by another virtual imaging distance lens element. For example, the second virtual imaging distance lens element may have a spherical refractive power of +0.65 diopter. This may allow the user to see through the optical assembly correctly. In some examples, the second virtual imaging distance (VID2) lens element may provide variable visible transmission in the presence of ambient light to control the display contrast. This may facilitate use of the optical assembly 600 in both indoor and outdoor environments, e.g., with a dimmer. The second virtual imaging distance (VID2) lens element may be able to selectively control the amount of light that is passed through from the outside environment to promote consistency of the display contrast. In some examples, the second virtual imaging distance (VID2) lens element provides protection against environmental pollution, damage, and wear and tear associated with usage.

In some examples, the optical assembly 600 may include a holographic optical element (HOE). The holographic optical element may diffract near infrared (nIR) light from the eye reflection (e.g., glint) toward an optical sensor. Using the holographic optical element may result in faster stereo view calibration for eye-tracking, as well as faster eye-tracking authentication.

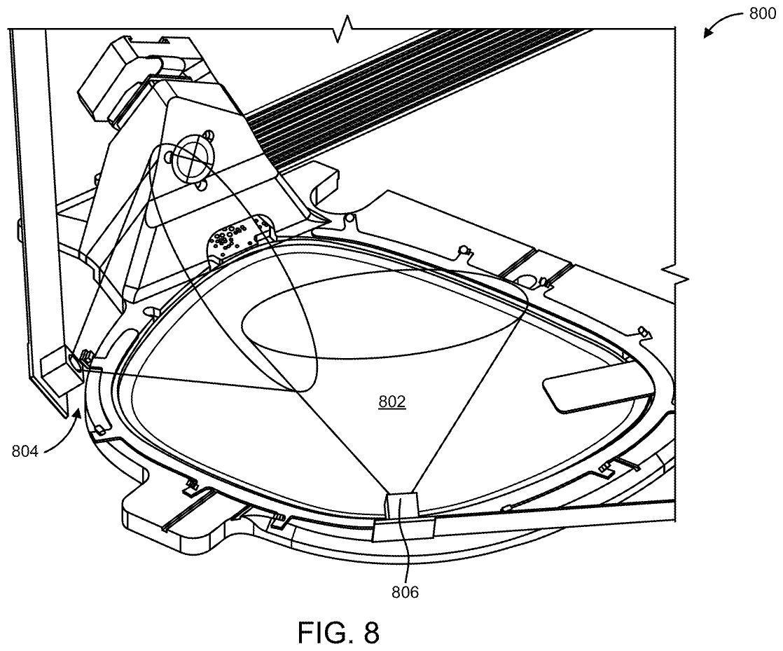

In some examples, an optical assembly may be incorporated into a head-mounted display (HMD) device. FIG. 8 illustrates a diagram of an example head-mounted display (HMD) device 800 according to various examples. The head-mounted display (HMD) device 800 may include an optical assembly (OSM) 802 as described herein. In some examples, the optical assembly 802 includes integrated near infrared (nIR) micro light emitting diodes (LEDs) as illumination sources. Additional near infrared (nIR) micro light emitting diodes (LEDs) may be located on a tapering edge of the frame and may be oriented to point toward the rotational center of the user's eyeball as additional illumination sources.

In some examples, the head-mounted display (HMD) device 800 includes direct-view camera modules 804, 806 mounted on a frame 808 of the head-mounted display (HMD) device 800. The direct-view camera modules 804, 806 are positioned to capture images of the user's eyes when the eyes are illuminated by the near infrared (nIR) micro light emitting diodes (LEDs). Reflections (e.g., glints) in the images may be used to determine a direction of a gaze of the user.

In some examples, the direct-view camera modules 804, 806 may be operable at least at the wavelength range between 800 nm and 965 nm with a 50% cutoff. The dimensions of the direct-view camera modules 804, 806 may be less than 3 mm by 3 mm to ensure that the direct-view camera modules 804, 806 are properly sized for the frame of the head-mounted display (HMD) device 800. The frame may be tapered on its edge to facilitate placement of the direct-view camera modules 804, 806 at an angle in the range of approximately 10° to 800.

In some examples, the working distance of the direct-view camera modules 804, 806 may be between 13 mm and 42 mm. The diagonal field of view of the direct-view camera modules 804, 806 may be at least 60°. In some examples, the direct-view camera modules 804, 806 may have a resolution of at least 1 pixel per mm at the object plane.

Additional Exemplary Eye Tracking Systems with Micro LEDs

Eye tracking (ET) technology has many applications for augmented reality and virtual reality devices. An often utilized eye-tracking technique may be image-based, which may use illumination sources and cameras to track pupil and corneal reflections (e.g., glints) and detect the gaze direction of an eye. Some existing eye tracking systems may have challenges in reducing eye gaze error. To reduce the eye gaze error, it may be important to generate enough separated bright glints formed in a spherical region of a cornea, of an eye of a user, close to the eye pupil center at all the possible gaze directions. Further, some existing eye tracking systems may have difficulty to cover a broad population of users having different eye/head shapes and sizes and different degrees of vision impairment, while using augmented reality or virtual reality in different scenarios. In addition, some existing eye tracking systems may face challenges in achieving and balancing other system requirements such as low power consumption, reduced size/weight, aesthetics, reliability, manufacturability, and low costs.

In view of the foregoing drawbacks and in order to achieve these system requirements, it may be beneficial to provide an efficient and reliable eye tracking system having a new architecture for illumination and sensing components.

Some embodiments of the present disclosure will now be described more fully hereinafter with reference to the accompanying drawings, in which some, but not all embodiments of the disclosure are shown. Indeed, various embodiments of the disclosure may be embodied in many different forms and should not be construed as limited to the embodiments set forth herein. Like reference numerals refer to like elements throughout. As used herein, the terms “data,” “content,” “information” and similar terms may be used interchangeably to refer to data capable of being transmitted, received and/or stored in accordance with embodiments of the disclosure. Moreover, the term “exemplary”, as used herein, is not provided to convey any qualitative assessment, but instead merely to convey an illustration of an example. Thus, use of any such terms should not be taken to limit the spirit and scope of embodiments of the disclosure.

As defined herein a “computer-readable storage medium,” which refers to a non-transitory, physical or tangible storage medium (e.g., volatile or non-volatile memory device), may be differentiated from a “computer-readable transmission medium,” which refers to an electromagnetic signal.

As referred to herein, glint(s) or glint image(s) may refer to detection, or image capture, of intended light reflected at an angle from a surface of one or more eyes. The light may be illuminated by a light source(s) onto the one or more eyes (e.g., a cornea of the eyes).

As referred to herein, a direct view camera(s) may refer to a camera(s) that is configured to directly view an eye(s) of a user. The direct view camera(s) may, for example, be arranged/pointed towards an eye(s) of a user such that the direct view camera(s) may capture a glint image(s) and/or pupil image(s).

As referred to herein, a Metaverse may denote an immersive virtual space or world in which devices may be utilized in a network in which there may, but need not, be one or more social connections among users in the network or with an environment in the virtual space or world. A Metaverse or Metaverse network may be associated with three-dimensional (3D) virtual worlds, online games (e.g., video games), one or more content items such as, for example, images, videos, non-fungible tokens (NFTs) and in which the content items may, for example, be purchased with digital currencies (e.g., cryptocurrencies) and other suitable currencies. In some examples, a Metaverse or Metaverse network may enable the generation and provision of immersive virtual spaces in which remote users may socialize, collaborate, learn, shop and/or engage in various other activities within the virtual spaces, including through the use of Augmented/Virtual/Mixed Reality.

It is to be understood that the methods and systems described herein are not limited to specific methods, specific components, or to particular implementations. It is also to be understood that the terminology used herein is for the purpose of describing particular embodiments only and is not intended to be limiting.

### Exemplary System Architecture

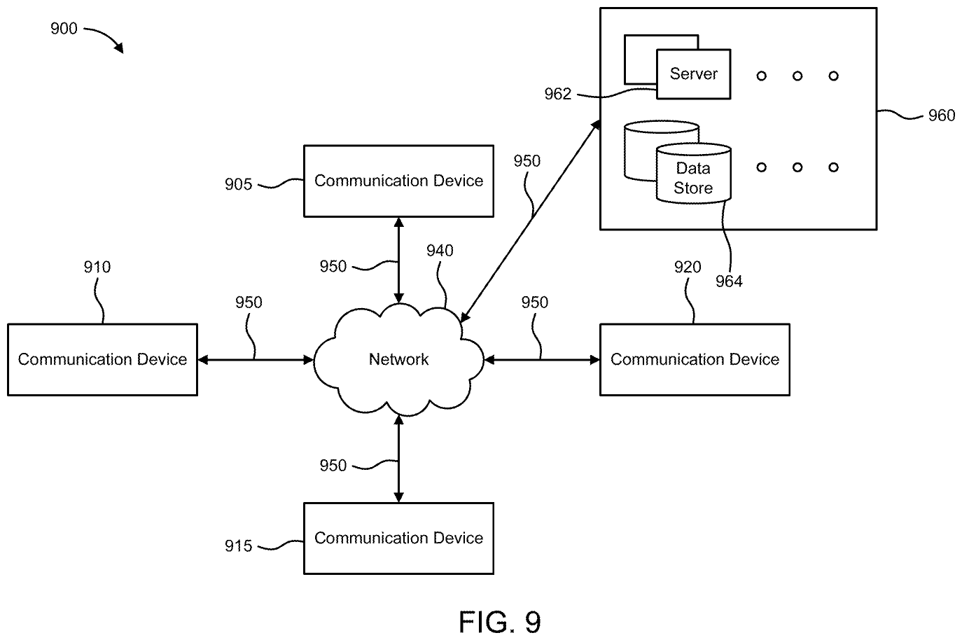

Reference is now made to FIG. 9, which is a block diagram of a system according to exemplary embodiments. As shown in FIG. 9, the system 900 may include one or more communication devices 905, 910, 915 and 920 and a network device 960. Additionally, the system 900 may include any suitable network such as, for example, network 940. In some examples, the network 940 may be a Metaverse network. In other examples, the network 940 may be any suitable network capable of provisioning content and/or facilitating communications among entities within, or associated with the network. As an example and not by way of limitation, one or more portions of network 940 may include an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, a portion of the Public Switched Telephone Network (PSTN), a cellular telephone network, or a combination of two or more of these. Network 940 may include one or more networks 940.

Links 950 may connect the communication devices 905, 910, 915 and 920 to network 940, network device 960 and/or to each other. This disclosure contemplates any suitable links 950. In some exemplary embodiments, one or more links 950 may include one or more wireline (such as for example Digital Subscriber Line (DSL) or Data Over Cable Service Interface Specification (DOCSIS)), wireless (such as for example Wi-Fi or Worldwide Interoperability for Microwave Access (WiMAX)), or optical (such as for example Synchronous Optical Network (SONET) or Synchronous Digital Hierarchy (SDH)) links. In some exemplary embodiments, one or more links 950 may each include an ad hoc network, an intranet, an extranet, a VPN, a LAN, a WLAN, a WAN, a WWAN, a MAN, a portion of the Internet, a portion of the PSTN, a cellular technology-based network, a satellite communications technology-based network, another link 950, or a combination of two or more such links 950. Links 950 need not necessarily be the same throughout system 900. One or more first links 950 may differ in one or more respects from one or more second links 950.

In some exemplary embodiments, communication devices 905, 910, 915, 920 may be electronic devices including hardware, software, or embedded logic components or a combination of two or more such components and capable of carrying out the appropriate functionalities implemented or supported by the communication devices 905, 910, 915, 920. As an example, and not by way of limitation, the communication devices 905, 910, 915, 920 may be a computer system such as for example smart glasses, an augmented/virtual reality device, a desktop computer, notebook or laptop computer, netbook, a tablet computer (e.g., a smart tablet), e-book reader, Global Positioning System (GPS) device, camera, personal digital assistant (PDA), handheld electronic device, cellular telephone, smartphone, smart watches, charging case, or any other suitable electronic device, or any suitable combination thereof. The communication devices 905, 910, 915, 920 may enable one or more users to access network 940. The communication devices 905, 910, 915, 920 may enable a user(s) to communicate with other users at other communication devices 905, 910, 915, 920.

Network device 960 may be accessed by the other components of system 900 either directly or via network 940. As an example and not by way of limitation, communication devices 905, 910, 915, 920 may access network device 960 using a web browser or a native application associated with network device 960 (e.g., a mobile social-networking application, a messaging application, another suitable application, or any combination thereof) either directly or via network 940. In particular exemplary embodiments, network device 960 may include one or more servers 962. Each server 962 may be a unitary server or a distributed server spanning multiple computers or multiple datacenters. Servers 962 may be of various types, such as, for example and without limitation, web server, news server, mail server, message server, advertising server, file server, application server, exchange server, database server, proxy server, another server suitable for performing functions or processes described herein, or any combination thereof. In particular exemplary embodiments, each server 962 may include hardware, software, or embedded logic components or a combination of two or more such components for carrying out the appropriate functionalities implemented and/or supported by server 962. In particular exemplary embodiments, network device 960 may include one or more data stores 964. Data stores 964 may be used to store various types of information. In particular exemplary embodiments, the information stored in data stores 964 may be organized according to specific data structures. In particular exemplary embodiments, each data store 964 may be a relational, columnar, correlation, or other suitable database. Although this disclosure describes or illustrates particular types of databases, this disclosure contemplates any suitable types of databases. Particular exemplary embodiments may provide interfaces that enable communication devices 905, 910, 915, 920 and/or another system (e.g., a third-party system) to manage, retrieve, modify, add, or delete, the information stored in data store 964.

Network device 960 may provide users of the system 900 the ability to communicate and interact with other users. In particular exemplary embodiments, network device 960 may provide users with the ability to take actions on various types of items or objects, supported by network device 960. In particular exemplary embodiments, network device 960 may be capable of linking a variety of entities. As an example and not by way of limitation, network device 960 may enable users to interact with each other as well as receive content from other systems (e.g., third-party systems) or other entities, or to allow users to interact with these entities through an application programming interfaces (API) or other communication channels.

It should be pointed out that although FIG. 9 shows one network device 960 and four communication devices 905, 910, 915 and 920 any suitable number of network devices 960 and communication devices 905, 910, 915 and 920 may be part of the system of FIG. 9 without departing from the spirit and scope of the present disclosure.

### Exemplary Artificial Reality System

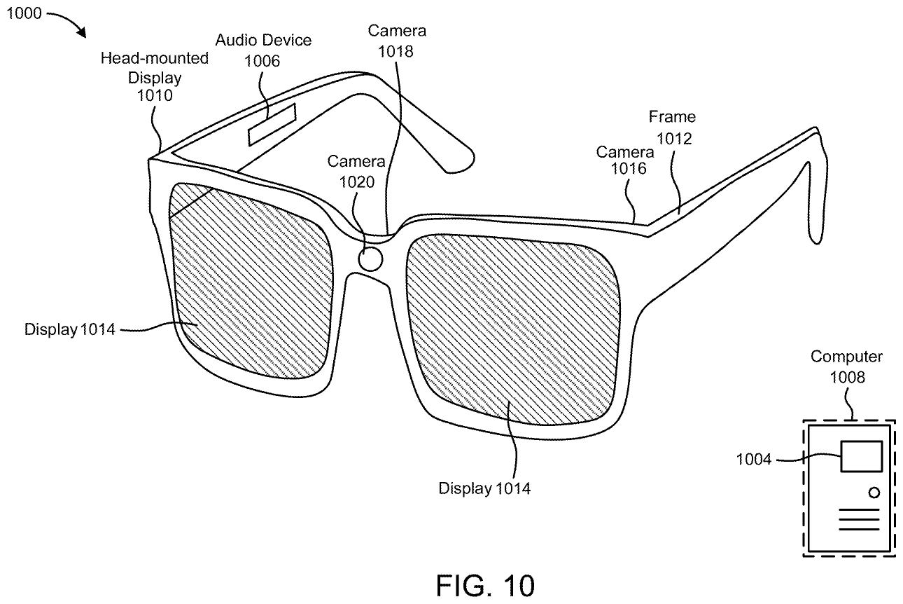

FIG. 10 illustrates an example artificial reality system 1000. The artificial reality system 1000 (also referred to herein as artificial reality device 1000) may include a HMD 1010 (e.g., smart glasses) comprising a frame 1012, one or more displays 1014, and a computing device 1008 (also referred to herein as computer 1008). In some exemplary embodiments, the HMD 1010 may be one or more of the communication devices 905, 910, 915, 920. The displays 1014 may be transparent or translucent allowing a user wearing the HMD 1010 to look through the displays 1014 to see the real world (e.g., real world environment) and displaying visual artificial reality content to the user at the same time.

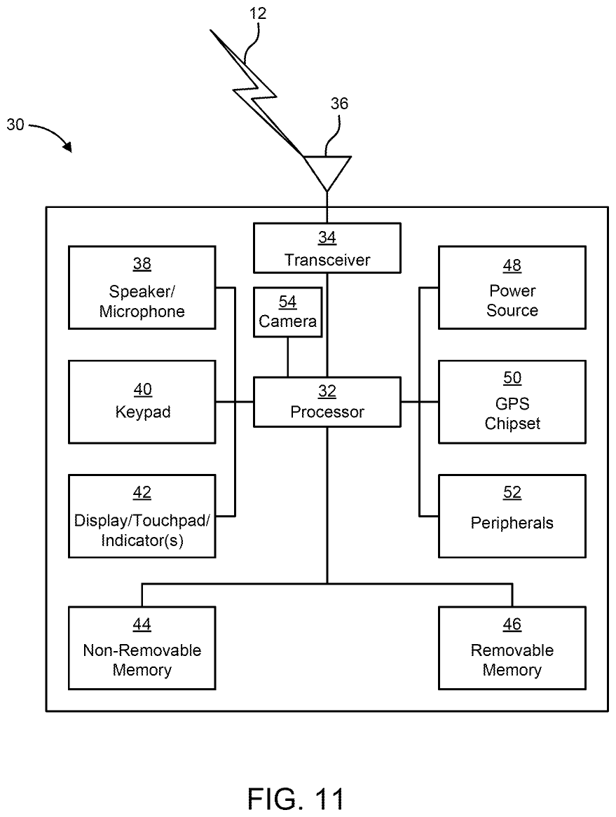

In some exemplary embodiments the displays 1014 may include a multi-functional optical module. The multi-functional optical module may include a plurality of optical layers. For example, the multi-functional optical module of the displays 1014 may include a layer 1 (L1) as an inner layer closest to an eye(s) of a user. In an example embodiment, the layer 1 may be a layer comprised of glass. The multi-functional optical module may also include an optical clear adhesive (OCA) layer which may be a transparent layer bonded to a layer 1, as described more fully below. Additionally, the multi-functional optical module may include a patterned substrate including micro-LEDs layer. Wires/traces connected to each of the micro-LEDs may be connected to a printed circuit board assembly (PCBA) and the PCBA may be connected to a PCBA LED driver, as described more fully below. The PCBA LED driver may, for example, be an integrated circuit (IC), an IC chip or the like. The multi-functional optical module may also include an anti-refractive layer (e.g., an optical film layer) which may include an anti-refractive and protective coating. In some example embodiments, the anti-refractive layer may be a layer of the multi-functional optical module closest to a real world environment that a user may be viewing via the artificial reality system 1000. In some other exemplary embodiments, the multi-functional optical module may include one or more additional layers. The HMD 1010 may include an audio device 1006 (e.g., speaker/microphone 38 of FIG. 11) that may provide audio artificial reality content to users. The HMD 1010 may include one or more cameras 1020 which may capture images and/or videos of environments. In one exemplary embodiment, the HMD 1010 may include a camera 1016 and a camera 1018 which may be rear-facing cameras tracking movement and/or gaze of a user's eyes.

The camera(s) 1020 may be a forward-facing camera capturing images and/or videos of the environment that a user wearing the HMD 1010 may view. The HMD 1010 may include an eye tracking system to track the vergence movement of the eyes of the user wearing the HMD 1010. In one exemplary embodiment, the camera 1016 and the camera 1018 may be part of the eye tracking system. In some exemplary embodiments, the cameras 1016, 1018 may be cameras configured to view at least one eye of a user to capture a glint image(s). In some other exemplary embodiments, the HMD 1010 may include additional cameras 1016, 1018 to facilitate viewing of each of the eyes of a user to enhance the capture of a glint image(s). The HMD 1010 may include a microphone of the audio device 1006 to capture voice input from the user. The augmented reality system 1000 may further include a controller 1004 (e.g., processor 32 of FIG. 11) comprising a trackpad and one or more buttons. The controller may receive inputs from users and relay the inputs to the computing device 1008. The controller may also provide haptic feedback to one or more users. The computing device 1008 may be connected to the HMD 1010 and the controller through cables or wireless connections. The computing device 1008 may control the HMD 1010 and the controller to provide the augmented reality content to and receive inputs from one or more users. In some example embodiments, the controller (e.g., processor 32 of FIG. 11) may be a standalone controller or integrated within the HMD 1010. The computing device 1008 may be a standalone host computer device, an on-board computer device integrated with the HMD 1010, a mobile device, or any other hardware platform capable of providing artificial reality content to and receiving inputs from users. In some exemplary embodiments, HMD 1010 may include an augmented reality system/virtual reality system/mixed reality system.

### Exemplary Communication Device

FIG. 11 illustrates a block diagram of an exemplary hardware/software architecture of a communication device such as, for example, user equipment (UE) 30. In some exemplary embodiments, the UE 30 may be any of communication devices 905, 910, 915, 920. In some exemplary embodiments, the UE 30 may be a computer system such as for example smart glasses, an augmented/virtual reality device, a desktop computer, notebook or laptop computer, netbook, a tablet computer (e.g., a smart tablet), e-book reader, GPS device, camera, personal digital assistant, handheld electronic device, cellular telephone, smartphone, smart watch, charging case, or any other suitable electronic device. As shown in FIG. 11, the UE 30 (also referred to herein as node 30) may include a processor 32, non-removable memory 44, removable memory 46, a speaker/microphone 38, a keypad 40, a display, touchpad, and/or indicators 42, a power source 48, a global positioning system (GPS) chipset 50, and other peripherals 52. The power source 48 may be capable of receiving electric power for supplying electric power to the UE 30. For example, the power source 48 may include an alternating current to direct current (AC-to-DC) converter allowing the power source 48 to be connected/plugged to an AC electrical receptable and/or Universal Serial Bus (USB) port for receiving electric power. The UE 30 may also include one or more cameras 54. In an exemplary embodiment, the camera(s) 54 may be a smart camera configured to sense images/video appearing within one or more bounding boxes. The UE 30 may also include communication circuitry, such as a transceiver 34 and a transmit/receive element 36. It will be appreciated the UE 30 may include any sub-combination of the foregoing elements while remaining consistent with an embodiment.

The processor 32 may be a special purpose processor, a digital signal processor (DSP), a plurality of microprocessors, one or more microprocessors in association with a DSP core, a controller, a microcontroller, Application Specific Integrated Circuits (ASICs), Field Programmable Gate Array (FPGAs) circuits, any other type of integrated circuit, a state machine, and the like. In general, the processor 32 may execute computer-executable instructions stored in the memory (e.g., memory 44 and/or memory 46) of the node 30 in order to perform the various required functions of the node. For example, the processor 32 may perform signal coding, data processing, power control, input/output processing, and/or any other functionality that enables the node 30 to operate in a wireless or wired environment. The processor 32 may run application-layer programs (e.g., browsers) and/or radio access-layer (RAN) programs and/or other communications programs. The processor 32 may also perform security operations such as authentication, security key agreement, and/or cryptographic operations, such as at the access-layer and/or application layer for example.

The processor 32 is coupled to its communication circuitry (e.g., transceiver 34 and transmit/receive element 36). The processor 32, through the execution of computer executable instructions, may control the communication circuitry in order to cause the node 30 to communicate with other nodes via the network to which it is connected.

The transmit/receive element 36 may be configured to transmit signals to, or receive signals from, other nodes or networking equipment. For example, in an exemplary embodiment, the transmit/receive element 36 may be an antenna configured to transmit and/or receive radio frequency (RF) signals. The transmit/receive element 36 may support various networks and air interfaces, such as wireless local area network (WLAN), wireless personal area network (WPAN), cellular, and the like. In yet another exemplary embodiment, the transmit/receive element 36 may be configured to transmit and/or receive both RF and light signals. It will be appreciated that the transmit/receive element 36 may be configured to transmit and/or receive any combination of wireless or wired signals. The transmit/receive element 36 may also be configured to connect the UE 30 to an external communications network, such as network 12, to enable the UE 30 to communicate with other nodes (e.g., other UEs 30, network device 960, etc.) of the network.

The transceiver 34 may be configured to modulate the signals that are to be transmitted by the transmit/receive element 36 and to demodulate the signals that are received by the transmit/receive element 36. As noted above, the node 30 may have multi-mode capabilities. Thus, the transceiver 34 may include multiple transceivers for enabling the node 30 to communicate via multiple radio access technologies (RATs), such as universal terrestrial radio access (UTRA) and Institute of Electrical and Electronics Engineers (IEEE 802.11), for example.

The processor 32 may access information from, and store data in, any type of suitable memory, such as the non-removable memory 44 and/or the removable memory 46. For example, the processor 32 may store session context in its memory, as described above. The non-removable memory 44 may include RAM, ROM, a hard disk, or any other type of memory storage device. The removable memory 46 may include a subscriber identity module (SIM) card, a memory stick, a secure digital (SD) memory card, and the like. In other exemplary embodiments, the processor 32 may access information from, and store data in, memory that is not physically located on the node 30, such as on a server or a home computer.

The processor 32 may receive power from the power source 48, and may be configured to distribute and/or control the power to the other components in the node 30. The power source 48 may be any suitable device for powering the node 30. For example, the power source 48 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like. The processor 32 may also be coupled to the GPS chipset 50, which may be configured to provide location information (e.g., longitude and latitude) regarding the current location of the node 30. It will be appreciated that the node 30 may acquire location information byway of any suitable location-determination method while remaining consistent with an exemplary embodiment.

### Exemplary System Operation

The exemplary embodiments are described for developing/creating a new multi-functional optical module having integrated near-infrared micro-LEDs, as illumination sources, for an eye tracking system(s) included in smart glasses (e.g., artificial reality system 1000). The eye tracking system(s) may utilize the multi-functional optical module that includes a plurality of optical layers. The multi-functional optical module including the optical layers may be integrated in a display (e.g., lenses (e.g., display 1014)) of the smart glasses. The multi-functional optical module may include a cluster of micro-LEDs utilized as illumination sources. In this regard, the micro-LEDs may be embedded within the display (e.g., in-field LEDs). In an exemplary embodiment, the micro-LEDs may be infrared (IR) LEDs. In some examples, the micro-LEDs may have a radiant flux greater than 2 milliwatts (mW) with an emission cone angle greater than 60° and wall plug efficiency (WPE) greater than 5%. In some other examples, the micro-LEDs may have other radiant fluxes with other emission cone angles and other wall plug efficiencies. Additionally, the eye tracking system may include at least two cameras (e.g., camera 1016, camera 1018) (e.g., near-infrared cameras) mounted to the frame (e.g., frame 1012) of the smart glasses. In some examples, the cameras may operate within a wavelength range from about 800 nm to about 1,000 nm. In some examples, the length and width of each camera may be less than 3 mm×3 mm, and the field of depth of the cameras may be between 10 mm-60 mm. Furthermore, in some examples, the diagonal field of view (FOV) of each camera may be more than 60°, and each camera may have a resolution of more than 1 pixel per mm at the object plane. In other examples, the length and width of the cameras and the field of depth of the cameras may be associated with other values. Additionally, the diagonal FOV of the cameras may be associated with other angles and the cameras may have other resolutions at the object plane.

The micro-LEDs, as the illumination sources, may for example illuminate nIR light onto the face of a user to generate a glint(s), for example, a reflection(s) of the illumination sources on an eye(s) (e.g., a cornea(s)) of a user. At least two cameras (e.g., camera 1016 and the camera 1018) on the frame (e.g., frame 1012) of the smart glasses may monitor the eye(s) of the user and may capture an image(s) (e.g., a glint image(s), an image(s) of a pupil) of the reflection. The glint(s)/glint image(s) and/or image(s) of the pupil may be utilized, by a controller (e.g., controller 1004) of the smart glasses, to determine a gaze, or gaze direction, of a user's eye(s).

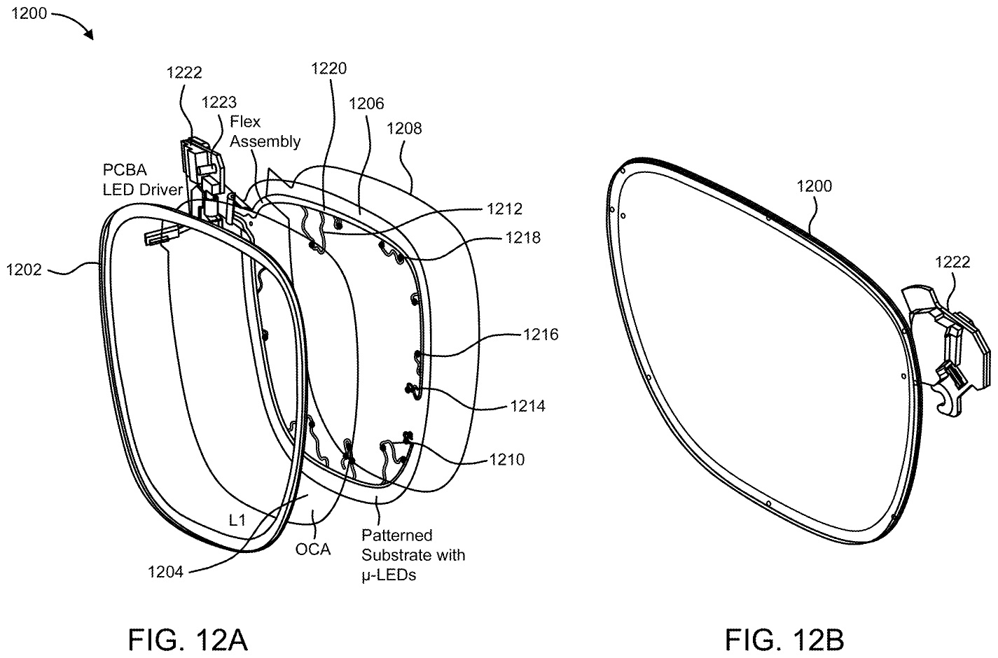

Referring now to FIG. 12A, a diagram illustrating a multi-functional optical module is provided according to an exemplary embodiment. In the exemplary embodiment of FIG. 12A, the multi-functional optical module 1200 (also referred to herein as MFOM 1200) may include an optical layer 1 (L1) 1202, an optical clear adhesive (OCA) layer 1204, an optical patterned substrate including micro-LEDs layer 1206 and an anti-refractive optical layer 1208. In some other exemplary embodiments, the multi-functional optical module 1200 may include one or more additional optical layers.

The L1 1202 may be comprised of glass, for example, and may be on an inner side (e.g., eye side) of the multi-functional optical module 1200 closest to an eye of a user. In some exemplary embodiments, the L1 1202 may include a prescription (e.g., a prescription for myopia, hypermetropia or other eye conditions) for an eye(s) of a user. The L1 1202 may also be referred to herein as a virtual imaging distance (VID1) lens layer. The OCA layer 1204 may be a transparent adhesive layer (e.g., glue) to bond the L1 1202 to the OCA layer 1204 and to bond the patterned substrate including micro-LEDs layer 1206 to the OCA layer 1204.

The pattered substrate including micro-LEDs layer 1206 of the multi-functional optical module 1200 may include a cluster of micro-LEDs, as illumination sources. The pattered substrate including micro-LEDs layer 1206 may also include wires (also referred to herein as traces) in which each of the respective wires (e.g., wire 1210, wire 1212) may connect respective micro-LEDs to the PCBA 1220. The PCBA 1220 may also be referred to herein as flex assembly 1220. In the example embodiment of FIG. 12A, as described above, the patterned substrate including micro-LEDs layer 1206 may include multiple (e.g., a set) micro-LEDs (e.g., LED 1214, LED 1216, LED 1218). In some example embodiments, the patterned substrate including micro-LEDs layer 1206 may include at least 6 micro-LEDs. In other exemplary embodiments, the patterned substrate including micro-LEDs layer 1206 may include any other suitable quantity of micro-LEDs (e.g., less than 6 micro-LEDs, at least 7 micro-LEDs, etc.). Since the micro-LEDs (e.g., LED 1214, LED 1216, LED 1218) may be in the field of view of a display/lens (e.g., display 1014) that a user may view, the micro-LEDs may be in-field LEDs (e.g., in-field LEDs of a lens layer of smart glasses). In one example embodiment, the micro-LEDs may be arranged on a tapering edge of a display (e.g., display 1014) pointing toward a rotational center of an eyeball of a user. In other example embodiments, the micro-LEDs may be arranged in any other suitable manner in the display (e.g., display 1014).

The substrate of the patterned substrate including the micro-LEDs layer 1206 may include the wires (e.g., wire 1210, wire 1212), which may be inconspicuous conductive wires (e.g., cooper wires) and/or transparent conducive electrodes (such as e.g., indium doped tin oxide, silver nanowires, or metallic mesh) electrically connecting the micro-LEDs (e.g., LED 1214, LED 1216, LED 1218) to the PCBA 1220. A size of the wires may be small/thin such as, for example, less than 25 μm to ensure the wires are inconspicuous (e.g., unable to be seen by an eye). The PCBA 1220 may be bonded to the substrate using a conductive film such as, for example, anisotropic conductive film (ACF). Adhesives and other materials (e.g., self-assembled anisotropic conductive particles (SAP), solder paste, etc.) may fully encapsulate and edge-seal the micro-LEDs and electrically conductive wires/traces. The PCBA 1220 may be a flexible circuit board connected to each of the wires of the patterned substrate including micro-LEDs layer 1206.

In an instance in which the PCBA 1220 may be connected to a PCBA LED driver 1222, each of the micro-LEDs of the layer 1206 may be powered on by the PCBA LED driver 1222. In some examples, the PCBA LED driver 1222 may include, or be associated with, an electrically erasable programmable read only memory (EEPROM) (e.g., EEPROM 1223). The PCBA LED driver 1222 may control the voltage and current settings to the micro-LEDs to drive the micro-LEDs to emit light. The PCBA LED driver 1222 may control all of the micro-LEDs of the layer 1206 to illuminate light uniformly within eye safety limits. Additionally, the PCBA LED driver 1222 may automatically turn off power to the micro-LEDs in an instance in which the PCBA LED driver 1222 detects a short circuit or broke circuit, or other malfunction associated with a wire(s) or a micro-LED(s) to ensure eye safety. The PCBA LED driver 1222 may also limit/cap the drive current that flows through individual micro-LEDs at a safe setting (e.g., tens of milliamps (mA)), such that the emitted optical output power from each of the micro-LEDs may not exceed a safety limit. The PCBA LED driver 1222 may trigger/cause the illumination of light by the micro-LEDs to be emitted periodically. The direct view cameras (e.g., camera 1016, camera 1018) may be synchronized with the PCBA LED driver 1222 in an instance in which the PCB LED driver 1222 may trigger/cause the periodic emission of the light from the micro-LEDs. In this manner, the direct view cameras may be synchronized with the PCBA LED driver 1222 to capture a glint image(s) based on the reflection of the emitted light from the eye(s) of a user (e.g., a user utilizing smart glasses). In some examples, the PCBA LED driver 1222 may be an integrated circuit or an IC chip (e.g., a semiconductor chip).

The anti-refractive optical layer 1208 may be an optical film layer that provides protective and anti-refractive coating to the MFOM 1200. The protective and anti-refractive coating may minimize scratches on the surface of the anti-refractive optical layer 1208 and may facilitate the blocking of at least some rays of sunlight. In some example embodiments, the anti-refractive optical layer 1208 may be an outer layer of the MFOM 1200 such that it may be a layer closest to the real world environment that a user may view while wearing smart glasses (e.g., artificial reality system 1000). In other alternative examples, the MFOM 1200 may include additional layers and one or more of the additional layers may be a layer closest to the real world environment that a user may view while wearing smart glasses.

In some alternative examples, another optical module layer beyond the multi-functional optical module 1200 towards the real-world side view may be used for display of content (e.g., captured images/videos of the real-world, AR content, etc.). This other optical module layer may be an optical waveguide layer fabricated on a glass substrate that may be utilized to conduct or guide light emitted by a display. Such optical waveguide layer may be made using high refractive index materials, such as for example silicon carbide (SiC), surrounded by lower index materials (e.g., silicon dioxide (SiO2) glass), such that the optical waveguide layer may confine the light via total internal reflection along a guided direction.

Further, in some alternative examples, the multi-functional optical module 1200 may include an additional virtual imaging distance (VID2) lens layer having the power of −0.65 diopter (D) (e.g., spherical). In this regard, VID2 layer may be utilized by the multi-functional optical module 1200 to correct a −0.65 D from a layer L1 to obtain a clearer real-world view. For instance, a layer L1 with −0.65 D may be utilized to bring a captured image viewable by a display (e.g., display 1014) closer, for example, at an ideal view distance of ˜1.5 meters (m).

Referring now to FIG. 12B, a diagram illustrating a three-dimensional (3D) view of a multi-functional optical module integrated together and a rear view of a printed circuit board assembly LED driver connected to the multi-functional optical module is provided according to an example of the present disclosure. In the example of FIG. 12B, the L1 1202, the OCA layer 1204, the patterned substrate with micro-LEDs layer 1206 and the anti-refractive layer 1208 may be bonded (e.g., by adhesive) together such that the multi-functional optical module 1200 may be integrated and connected to the PCBA LED driver 1222. In some examples, the PCBA LED driver 1222 may be arranged in a temporal arm of a frame of smart glasses (e.g., artificial reality system 1000). For instance, in some examples, the PCBA LED driver 1222 may be bonded onto a flexible (flex) circuit that may be embedded in the temporal arm or top of the frame (e.g., frame 1012) of the smart glasses (e.g., artificial reality system 1000).

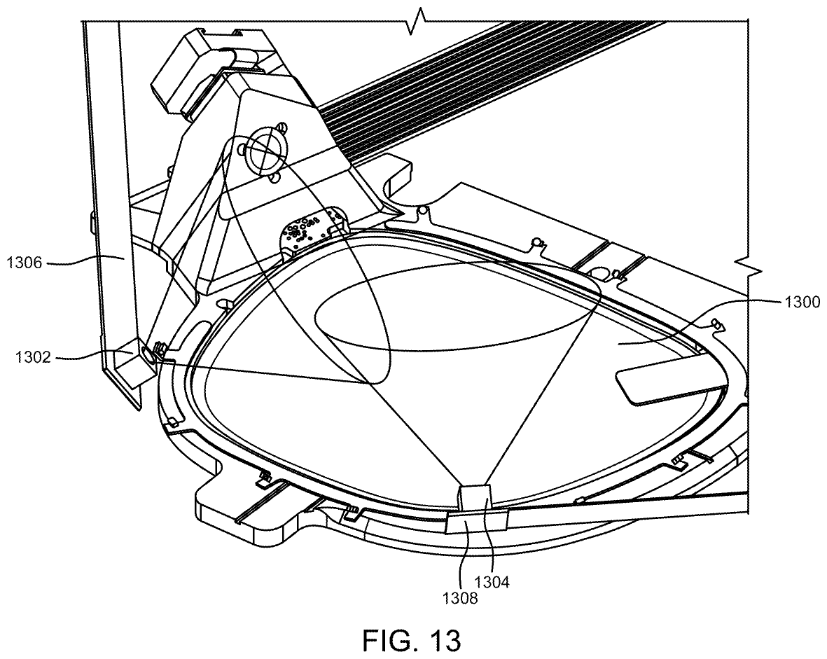

Referring now to FIG. 13, a diagram illustrating a portion of smart glasses including cameras in accordance with an exemplary embodiment is provided. For purposes of illustration, and not of limitation, a first camera 1302 (e.g., camera 1016) may be arranged on/in a temporal location (e.g., a temporal side 1306) on a frame (e.g., frame 1012) of the smart glasses (e.g., artificial reality system 1000) and a second camera 1304 (e.g., camera 1018) may be arranged on/in a nasal component 1308 of the frame of the smart glasses. Based on the first camera 1302 (e.g., camera 1016) being arranged on the temporal side 1306 (also referred to herein as temporal arm 1306) of the frame and the second camera 1304 (e.g., camera 1018) being arranged on the nasal component 1308 of the frame of the smart glasses, the first camera 1302 and the second camera 1304 may capture a full view in one or more images (e.g., a glint image(s), an image(s) of a pupil) of both sides of an eye of a user. The glint image(s) and/or pupil image(s) may be utilized by a controller (e.g., controller 1004) of the smart glasses to determine a gaze, or gaze direction, of an eye(s) of a user.

The first camera 1302 and the second camera 1304 may capture the image(s) (e.g., a glint image(s), a pupil image(s)) of the reflection from the eye(s) caused by the illumination of light emitted from the micro-LEDs of the multi-functional optional module 1300 (e.g., multi-functional optional module 1200). In other examples, the direct view cameras of the smart glasses may be arranged in other areas of the frame of the smart glasses. For example, the frame may be tapered on an edge to enable the placement of direct view cameras at an angle in the range of 10° to 80°. In other examples, the frame may be tapered on an edge to enable the placement of direct view cameras at other angles in other ranges. Additionally, in some other examples, the smart glasses may include more than two direct view cameras (e.g., cameras 1302, 1304).

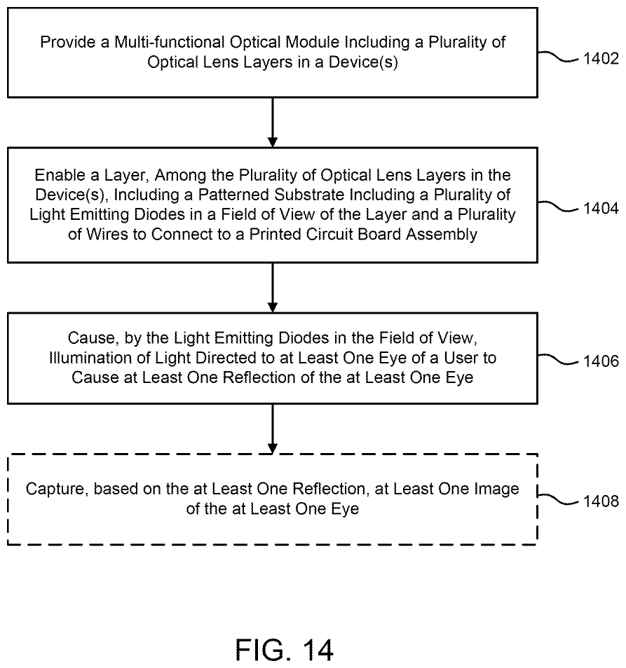

FIG. 14 illustrates an example flowchart illustrating operations for an eye tracking system according to an exemplary embodiment. At operation 1402, a device (e.g., artificial reality device 1000) may be provided with a multi-functional optical module (e.g., multi-functional optical module 1200) including a plurality of optical lens layers. At operation 1404, a device (e.g., artificial reality device 1000) may be enabled/provided with a layer (e.g., patterned substrate including micro-LEDs layer 1206), among the plurality of optical lens layers in the device. The layer may include a patterned substrate including a plurality of light emitting diodes (e.g., LED 1214, LED 1216, LED 1218) in a field of view of the layer and a plurality of wires (e.g., wire 1210, wire 1212) to connect to a printed circuit board assembly (e.g., PCBA 1220). The PCBA may be configured to connect to a controller (e.g., PCBA LED driver 1222). In some examples, the plurality of light emitting diodes may have a size less than 250 μm. In other examples, the plurality of light emitting diodes may have other suitable sizes.

At operation 1406, a device (e.g., artificial reality device 1000) may cause, by the light emitting diodes in the field of view, illumination of light directed to at least one eye of a user to cause at least one reflection of the at least one eye. The light may be near-infrared light. Optionally, at operation 1408, a device (e.g., artificial reality device 1000) may capture, based on the at least one reflection, one or more images of the at least one eye. The image(s) may be a glint image(s) (e.g., an image of the reflection of the eye(s)) and/or a pupil image(s). At least one or more direct view cameras (e.g., camera 1302, camera 1304) of the device may capture the one or more images. The device may determine a gaze, or gaze direction, of the at least one eye based on the captured one or more images. A first camera (e.g., camera 1302), among the two cameras, may for example be arranged on a temporal side (e.g., temporal arm 1306) of a frame (e.g., frame 1012) of the device. The first camera may be configured to capture a first image, at a first angle, of the reflection of the at least one eye. A second camera (e.g., camera 1304), among the two cameras, may for example be arranged on a nasal component (e.g., nasal component 1308) of the frame of the device. The second camera may be configured to capture a second image, at a second angle, of the reflection of the at least one eye. In other example embodiments, the first camera and the second camera may be arranged in other areas of the frame of the device. The multi-functional optical module (1200) may also include other optical layers such as a layer 1 1202, an OCA layer 1204, an anti-refractive layer 1208, as described above. Additionally, in some other exemplary embodiments, the multi-functional optical module may include additional optical layers.

### Alternative Embodiments

In the foregoing description, various examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

Although the methods and systems as described herein may be directed mainly to digital content, such as videos or interactive media, it should be appreciated that the methods and systems as described herein may be used for other types of content or scenarios as well. Other applications or uses of the methods and systems as described herein may also include social networking, marketing, content-based recommendation engines, and/or other types of knowledge or data-driven systems.

The foregoing description of the embodiments has been presented for the purpose of illustration; it is not intended to be exhaustive or to limit the patent rights to the precise forms disclosed. Persons skilled in the relevant art can appreciate that many modifications and variations are possible in light of the above disclosure.

Some portions of this description describe the example embodiments in terms of applications and symbolic representations of operations on information. These application(s) descriptions and representations may be commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Example embodiments also may relate to an apparatus for performing the operations herein. This apparatus may be specially constructed for the required purposes, and/or it may comprise a computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Example embodiments also may relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed:

1. A device comprising:
one or more processors;
at least one memory storing instructions;
a multi-functional optical module comprising a plurality of optical lens layers; and
a layer, among the plurality of optical lens layers, comprising a patterned substrate comprising a plurality of light emitting diodes in a field of view of the layer and a plurality of wires configured to connect to a printed circuit board assembly, and
wherein when the one or more processors execute the instructions, the device is configured to enable the light emitting diodes in the field of view to illuminate light directed to at least one eye of a user to cause at least one reflection of the at least one eye.

2. The device of claim 1, wherein the device comprises at least one of an artificial reality device, a head-mounted display, or smart glasses.

3. The device of claim 1, wherein a size of the light emitting diodes is less than 250 micrometers.

4. The device of claim 1, wherein the light comprises near-infrared light.

5. The device of claim 1, further comprising:
a plurality of cameras, wherein the plurality of cameras are configured to capture at least one glint image associated with the at least one reflection of the at least one eye caused by the light illuminated by the plurality of light emitting diodes.

6. The device of claim 5, wherein when the one or more processors execute the instructions, the device is configured to:
determine, based on the at least one glint image or pupil image, a gaze associated with the at least one eye.

7. The device of claim 5, further comprising:
a first camera, among the plurality of cameras, arranged on at least one temporal side of a frame of the device and wherein the first camera is configured to capture a first image, at a first angle, of the at least one reflection of the at least one eye.

8. The device of claim 5, further comprising:
a second camera, among the plurality of cameras, arranged on at least one nasal component of a frame of the device and wherein the second camera is configured to capture a second image, at a second angle, of the at least one reflection of the at least one eye.

9. The device of claim 1, wherein the printed circuit board assembly is flexible.

10. The device of claim 1, further comprising:
a controller configured to connect to the printed circuit board assembly and to control the plurality of light emitting diodes.

11. The device of claim 10, wherein the control comprises at least one of providing power, voltage or current to the plurality of light emitting diodes.

12. The device of claim 1, further comprising:
another layer, among the plurality of optical lens layers in the multi-functional optical module, closest, in relation to other layers of the plurality of optical lens layers, to the at least one eye.

13. The device of claim 12, wherein the another layer comprises glass.

14. The device of claim 12, wherein the another layer comprises a prescription associated with the at least one eye.

15. The device of claim 12, further comprising:
an optical clear adhesive layer, among the plurality of optical lens layers in the multi-functional optical module, between the layer and the another layer.

16. The device of claim 1, further comprising:
an anti-refractive layer, among the plurality of optical lens layers in the multi-functional optical module arranged on an outer side of the layer, wherein the anti-refractive layer is closest to a field of view of a real world environment that the at least one eye is configured to view.

17. The device of claim 1, wherein the plurality of light emitting diodes are arranged on an edge of the patterned substrate and point to a rotational center of an eyeball of the at least one eye.

18. A method comprising:
providing a multi-functional optical module comprising a plurality of optical lens layers in at least one device;
enabling a layer, among the plurality of optical lens layers in the at least one device, comprising a patterned substrate comprising a plurality of light emitting diodes in a field of view of the layer and a plurality of wires to connect to a printed circuit board assembly; and
causing, by the light emitting diodes in the field of view, illumination of light directed to at least one eye of a user to cause at least one reflection of the at least one eye.

19. The method of claim 18, wherein the at least one device comprises at least one of an artificial reality device, a head-mounted display, or smart glasses.

20. A computer-readable medium storing instructions that, when executed, cause:
facilitating illumination, by a plurality of light emitting diodes in a field of view of a layer among a plurality of optical lens layers in at least one device, of light directed to at least one eye of a user to cause at least one reflection of the at least one eye,
wherein a multi-functional optical module comprises the plurality of optical lens layers in the at least one device, and the layer comprises a patterned substrate comprising the plurality of light emitting diodes in the field of view of the layer and a plurality of wires to connect to a printed circuit board assembly; and
capturing, based on the at least one reflection, at least one image of the at least one eye.
